(19) United States
(12) Patent Application Publication
(10) Pub. No.: US 2026/0020224 A1
(43) Pub. Date: Jan. 15, 2026

(54) SEMICONDUCTOR DEVICE INCLUDING ACTIVE PATTERN

(71) Applicant: Samsung Electronics Co., Ltd., Suwon-si (KR)

(72) Inventors: Huiyeong PARK, Suwon-si (KR); Kiseok LEE, Suwon-si (KR); Hyeonkyu LEE, Suwon-si (KR); Hosang LEE, Suwon-si (KR); Yongkwan KIM, Suwon-si (KR); Huijung KIM, Suwon-si (KR); Taejin PARK, Suwon-si (KR); Sungsoo YIM, Suwon-si (KR)

(73) Assignee: Samsung Electronics Co., Ltd., Suwon-si (KR)

(21) Appl. No.: 19/173,965

(22) Filed: Apr. 9, 2025

(30) Foreign Application Priority Data
Jul. 15, 2024 (KR) 10-2024-0093124

(51) Int. Cl. H10B 12/00

(52) U.S. Cl. CPC H10B 12/315; H10B 12/05

(57) ABSTRACT

A semiconductor device is provided. The semiconductor device includes a first active pattern and a second active pattern arranged sequentially in a first horizontal direction, and a back gate electrode and a first word line spaced apart from each other in a second horizontal direction. Each of the first and second active patterns includes a first source/drain region, a second source/drain region, and a channel region. The back gate electrode includes a line portion having first regions facing the first and second active patterns and a second region between the first regions, a first protrusion protruding from the second region of the line portion in a direction toward the first word line, and a second protrusion protruding from the second region of the line portion in a direction away from the first word line.

### CROSS-REFERENCE TO RELATED APPLICATION(S)

This application claims benefit of priority to Korean Patent Application No. 10-2024-0093124 filed on Jul. 15, 2024, in the Korean Intellectual Property Office, the disclosure of which is incorporated herein by reference in its entirety.

### BACKGROUND

Some example embodiments relate to a semiconductor device including an active pattern and a method of forming the same.

Research has been conducted to reduce sizes of elements included in semiconductor devices and/or improve performance. For example, in a DRAM, research to more reliably and stably form elements having reduced sizes has been conducted, but as the sizes of elements are reduced, characteristics of the semiconductor device may deteriorate.

### SUMMARY

Some example embodiments provide a semiconductor device that may increase integration and/or improve performance.

Some example embodiments provide a method of forming a semiconductor device.

According to some example embodiments, a semiconductor device includes a first active pattern and a second active pattern arranged sequentially in a first horizontal direction, and a back gate electrode and a first word line spaced apart from each other in a second horizontal direction, the second horizontal direction being perpendicular to the first horizontal direction. Each of the first and second active patterns includes a first source/drain region, a second source/drain region at a level higher than a level of the first source/drain region, a channel region between the first source/drain region and the second source/drain region, and the channel region is further between the back gate electrode and the first word line. In a plan view, the back gate electrode includes a line portion having first regions respectively facing each of the first and second active patterns and a second region between the first regions, a first protrusion protruding from the second region of the line portion in a direction toward the first word line, and a second protrusion protruding from the second region of the line portion in a direction away from the first word line.

According to some example embodiments, a semiconductor device includes a first active pattern and a second active pattern, spaced apart from each other in a first horizontal direction, a back gate electrode and a first word line spaced apart from each other in a second horizontal direction, the second horizontal direction being perpendicular to the first horizontal direction, a gate dielectric structure between the first and second active patterns and the back gate electrode and between the each of first and second active patterns and the first word line, the gate dielectric structure extending below a lower surface of the back gate electrode and a lower surface of the first word line, and a buffer insulating structure below the gate dielectric structure. The buffer insulating structure surrounds a side surface of a lower region of each of the first and second active patterns. Each of the first and second active patterns includes a channel region between the back gate electrode and the first word line, and each of the first and second active patterns includes an inclined side surface so that a width of an upper surface thereof is smaller than a width of a lower surface thereof.

According to some example embodiments, a semiconductor device includes a first structure including a memory region, and a second structure bonded to the first structure and including a peripheral circuit region. The memory region includes a first active pattern and a second active pattern arranged sequentially in a first horizontal direction, a back gate electrode and a word line spaced apart from each other in a second horizontal direction, the second horizontal direction being perpendicular to the first horizontal direction, and a gate dielectric structure between the first and second active patterns and the back gate electrode, and t between the first and second active patterns and the word line. Each of the first and second active patterns includes a first source/drain region, a second source/drain region at a level higher than a level of the first source/drain region, and a channel region between the first source/drain region and second source/drain region. The channel region is between the back gate electrode and the word line. The gate dielectric structure includes a first gate dielectric portion disposed between the first and second active patterns and extending between the first and second active patterns.

### BRIEF DESCRIPTION OF DRAWINGS

The some example embodiments the present disclosure will be more clearly understood from the following detailed description, taken in conjunction with the accompanying drawings, in which:

FIGS. 1 to 3 are views illustrating a semiconductor device according to some example embodiments of the present disclosure;

FIG. 4 is a conceptual perspective view illustrating some examples of a semiconductor device according to some example embodiments of the present disclosure;

FIGS. 5A, 5B, 6A, 6B, 7A, and 7B are views illustrating examples of semiconductor devices according to some example embodiments of the present disclosure;

FIG. 8A is a cross-sectional view illustrating some examples of a semiconductor device according to some example embodiments of the present disclosure;

FIG. 8B is a cross-sectional view illustrating some examples of a semiconductor device according to some example embodiments of the present disclosure;

FIG. 9A is a cross-sectional view illustrating some examples of a semiconductor device according to some example embodiments of the present disclosure;

FIG. 9B is a cross-sectional view illustrating some examples of a semiconductor device according to some example embodiments of the present disclosure;

FIG. 9C is a cross-sectional view illustrating some examples of a semiconductor device according to some example embodiments of the present disclosure;

FIG. 10A is a cross-sectional view illustrating some examples of a semiconductor device according to some example embodiments of the present disclosure;

FIG. 10B is a cross-sectional view illustrating some examples of a semiconductor device according to some example embodiments of the present disclosure;

FIG. 10C is a cross-sectional view illustrating some examples of a semiconductor device according to some example embodiments of the present disclosure;

FIG. 11A is a cross-sectional view illustrating some examples of a semiconductor device according to some example embodiments of the present disclosure;

FIG. 11B is a cross-sectional view illustrating some examples of a semiconductor device according to some example embodiments of the present disclosure;

FIG. 11C is a cross-sectional view illustrating some examples of a semiconductor device according to some example embodiments of the present disclosure;

FIG. 12A is a cross-sectional view illustrating some examples of a semiconductor device according to some example embodiments of the present disclosure;

FIG. 12B is a cross-sectional view illustrating some examples of a semiconductor device according to some example embodiments of the present disclosure;

FIG. 13A is a cross-sectional view illustrating some examples of a semiconductor device according to some example embodiments of the present disclosure;

FIG. 13B is a cross-sectional view illustrating some examples of a semiconductor device according to some example embodiments of the present disclosure;

FIG. 13C is a cross-sectional view illustrating some examples of a semiconductor device according to some example embodiments of the present disclosure;

FIG. 14 is a cross-sectional view illustrating some examples of a semiconductor device according to some example embodiments of the present disclosure;

FIG. 15A is a cross-sectional view illustrating some examples of a semiconductor device according to some example embodiments of the present disclosure;

FIG. 15B is a cross-sectional view illustrating some examples of a semiconductor device according to some example embodiments of the present disclosure;

FIG. 16 is a cross-sectional view illustrating some examples of a semiconductor device according to some example embodiments of the present disclosure;

FIG. 17 is a cross-sectional view illustrating some examples of a semiconductor device according to some example embodiments of the present disclosure;

FIG. 18 is a cross-sectional view illustrating some examples of a semiconductor device according to some example embodiments of the present disclosure;

FIG. 19 is a plan view illustrating some examples of a semiconductor device according to some example embodiments of the present disclosure;

FIG. 20 is a plan view illustrating some examples of a semiconductor device according to some example embodiments of the present disclosure;

FIGS. 21A and 21B are plan views illustrating some examples of a semiconductor device according to some example embodiments of the present disclosure;

FIGS. 22A and 22B are views illustrating some examples of a semiconductor device according to some example embodiments of the present disclosure;

FIGS. 23A, 23B and 24 are views illustrating some examples of a semiconductor device according to some example embodiments of the present disclosure;

FIG. 25 is a process flowchart illustrating a method of forming a semiconductor device according to some example embodiments of the present disclosure;

FIGS. 26A to 26E are cross-sectional views illustrating some examples of a method of forming a semiconductor device according to some example embodiments of the present disclosure;

FIGS. 27A and 27B are cross-sectional views illustrating some examples of a method of forming a semiconductor device according to some example embodiments of the present disclosure;

FIGS. 28A and 28B are cross-sectional views illustrating some examples of a method of forming a semiconductor device according to some example embodiments of the present disclosure;

FIGS. 29A and 29B are cross-sectional views illustrating some examples of a method of forming a semiconductor device according to some example embodiments of the present disclosure; and

FIGS. 30A and 30B are cross-sectional views illustrating some examples of a method of forming a semiconductor device according to some example embodiments of the present disclosure.

### DETAILED DESCRIPTION

Hereinafter, the terms such as “upper,” “intermediate,” and “lower” may be replaced with other terms such as “first,” “second,” and “third” and may be used to describe elements of the specification. The terms such as “first,” “second,” and “third” may be used to describe various elements, but the elements are not limited thereto, and the “first element” could be termed “second element.” In the specification, terms such as “lower portion,” “upper portion,” “upper end,” “upper end” and “lower end” may be terms described based on the drawings.

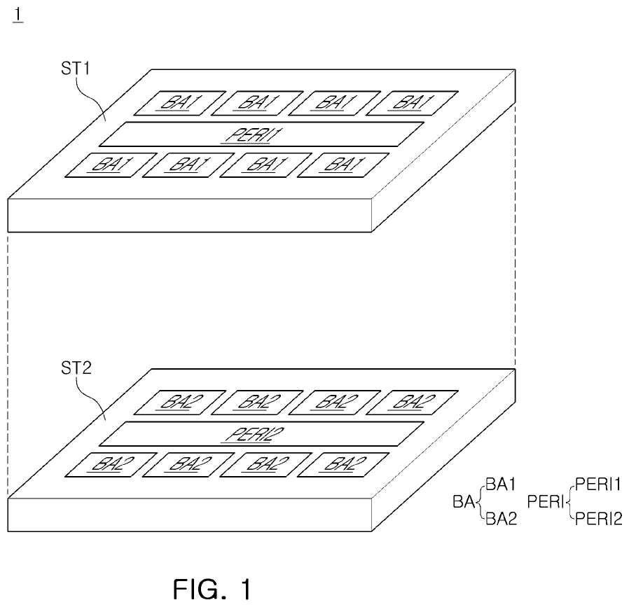

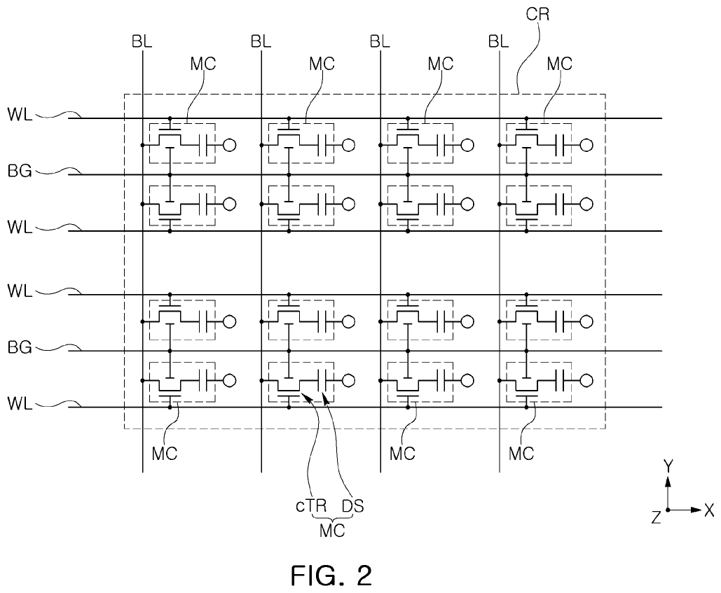

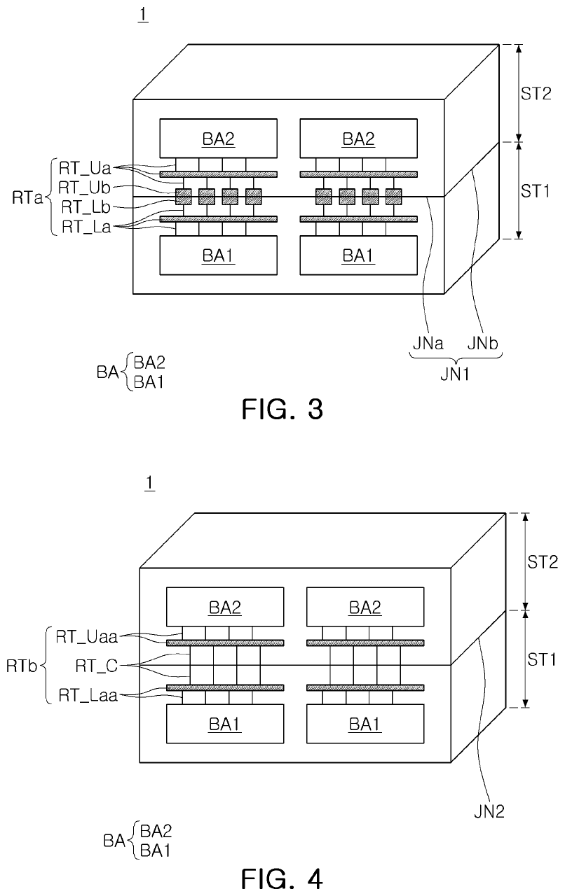

A semiconductor device according to some example embodiments of the present disclosure will be described with reference to FIGS. 1, 2, and 3. In FIGS. 1 to 3, FIG. 1 is a conceptual perspective view illustrating a semiconductor device according to some example embodiments of the present disclosure, FIG. 2 is a circuit diagram illustrating a memory region of a semiconductor device according to some example embodiments of the present disclosure, and FIG. 3 is a conceptual perspective view illustrating some examples of a semiconductor device according to some example embodiments of the present disclosure.

Referring to FIGS. 1, 2, and 3, a semiconductor device 1 according to some example embodiments may include a first structure ST1 and a second structure ST2 vertically overlapping the first structure ST1. The second structure ST2 may be disposed below the first structure ST1. According to some example embodiments, the second structure ST2 may be disposed on the first structure ST1.

In some example embodiments, the first structure ST1 may be a first chip structure including a memory region CR and a peripheral region, and the second structure ST2 may be a second chip structure including a second peripheral circuit. The first structure ST1 and the second structure ST2 may be formed by being bonded by a bonding process such as a wafer bonding process. Accordingly, the first structure ST1 may be in contact with and bonded to the second structure ST2.

The semiconductor device 1 may include a plurality of banks BA and an external peripheral region PERI.

The external peripheral region PERI may include a peripheral region PERI1 in the first structure ST1 and a second peripheral region PERI2 in the second structure ST2. The external peripheral region PERI may be a peripheral region in which peripheral circuits for input/output of data or commands, or input of power/ground are disposed.

Each of the plurality of banks BA may include a first bank area BA1 in the first structure ST1 and a second bank area BA2 in the second structure ST2.

The first bank area BA1 in the first structure ST1 may include a memory region CR. The memory region CA may include memory cells MC arranged in a first direction (X-direction) and a second direction (Y-direction), word lines WL connected to the memory cells MC and extending in the first direction (X-direction), and bit lines BL connected to the memory cells MC and extending in the second direction (Y-direction). The first direction (X-direction) and the second direction (Y-direction) may be perpendicular to each other. The word lines WL may intersect the memory region CA in the first direction (X-direction). The bit lines BL may intersect the memory region CA in the second direction (Y-direction). Each of the memory cells MC may include a data storage structure DS that may serve as a data storage structure and a cell transistor cTR electrically connected to the data storage structure DS. In a memory device such as a DRAM memory device, the data storage structure DS may be a cell capacitor that may store information. The memory region CA may further include back gate lines BG. Each of the back gate lines BG may be disposed between a pair of word lines WL adjacent to each other in the second direction (Y-direction) among the word lines WL. Each of the back gate lines BG may be disposed between vertical channel regions of the cell transistors cTR.

The second bank area BA2 in the second structure ST2 may include a sense amplifier electrically connected to the bit lines BL in the memory region CR, a sub-word line driver electrically connected to the word lines WL in the memory region CR, and a peripheral circuit such as a back gate control circuit electrically connected to the back gate lines BG in the memory region.

The first and second structures ST1 and ST2 may further include a routing interconnection structure RTa electrically connecting the first bank area BA1 and the second bank area BA2. For example, the routing interconnection structure RTa may include first routing interconnection structures RT_La and RT_Lb disposed in the first structure ST1 and second routing interconnection structures RT_Ua and RT_Ub disposed in the second structure ST2.

The first routing interconnection structures RT_La and RT_Lb may include a first interconnection structure RT_La electrically connected to the first bank area BA1 and first bonding pads RT_Lb electrically connected to the first interconnection structure RT_La. The second routing interconnection structures RT_Ua and RT_Ub may include a second interconnection structure RT_Ua electrically connected to the second bank area BA2 and second bonding pads RT_Ub electrically connected to the second interconnection structure RT_Ua.

The first bonding pads RT_Lb and the second bonding pads RT_Ub may be in contact with each other and bonded. For example, the first bonding pads RT_Lb and the second bonding pads RT_Ub may include copper and may be bonded to each other in an intermetallic bonding process. Accordingly, a bonding surface JN1 between the first structure ST1 and the second structure ST2 may include intermetallic bonding regions JNa in which the first bonding pads RT_Lb of the first structure ST1 and the second bonding pads RT_Ub of the second structure ST2 are bonded to each other, and inter-dielectric bonding regions JNb in which a dielectric of the first structure ST1 and a dielectric of the second structure ST2 are bonded to each other.

Next, some example embodiments of the routing interconnection structure RTa and the bonding surface JN1 described above will be described with reference to FIG. 4. FIG. 4 is a conceptual perspective view illustrating examples of the routing interconnection structure RTa and the bonding surface JN1 illustrated in FIG. 3.

In some example embodiments, referring to FIG. 4, the routing interconnection structure RTa described above in FIG. 3 may be replaced with a routing interconnection structure RTb in which the first bonding pads RT_Lb and the second bonding pads RT_Ub may be omitted, and the bonding surface JN1 described above in FIG. 3 may be replaced with a bonding surface JN2 in which the intermetallic bonding regions JNa may be omitted.

The routing interconnection structure RTb may include a first interconnection structure RT_Laa included in the first structure ST1 and electrically connected to the first bank area BA1, a second interconnection structure RT_Uaa included in the second structure ST2 and electrically connected to the second bank area BA2, and a connection structure RT_C extending from the first structure ST1 to the second structure ST2 and electrically connecting the first and second interconnection structures RT_Laa and RT_Uaa.

The bonding surface JN2 between the first structure ST1 and the second structure ST2 may be formed as an inter-dielectric bonding surface on which the dielectric of the first structure ST1 and the dielectric of the second structure ST2 are bonded to each other. The connection structure RT_C may penetrate through the bonding surface JN2.

Hereinafter, with reference to FIGS. 1 to 3, examples of the memory region CR of the first bank area BA1 of the first structure ST1 of the semiconductor device 1 will be described. Hereinafter, examples of the memory region CR illustrated in FIGS. 1 to 3 will be described, but in example embodiments described below, the routing interconnection structure RTa and the bonding surface JN1 illustrated in FIG. 3 may be replaced with the routing interconnection structure RTb and the bonding surface JN2 illustrated in FIG. 4. Additionally, example embodiments described below may be combined with each other to form one example embodiment.

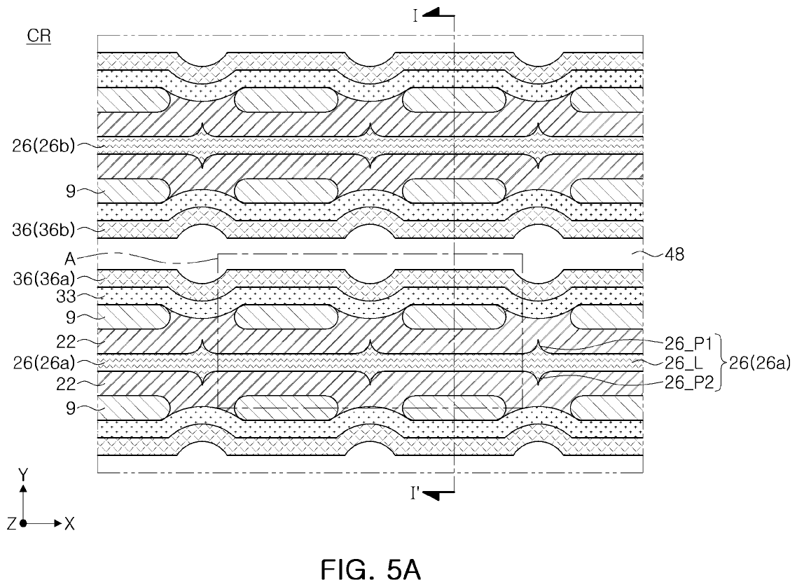

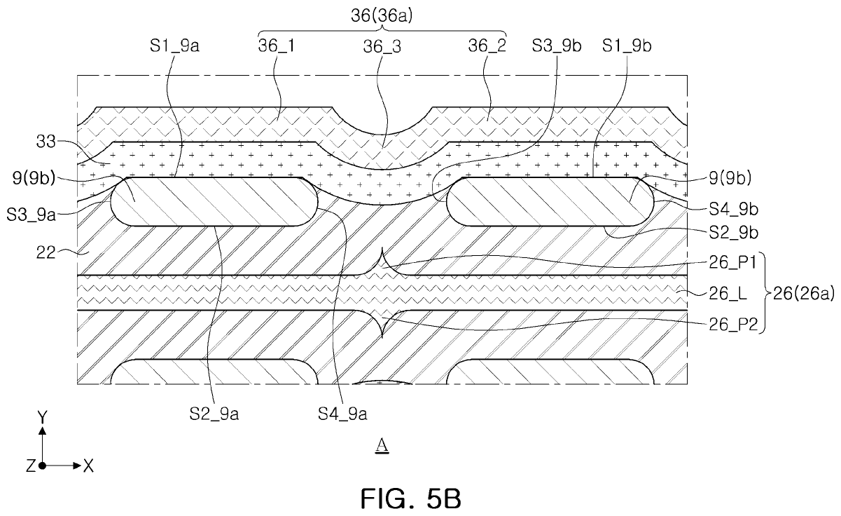

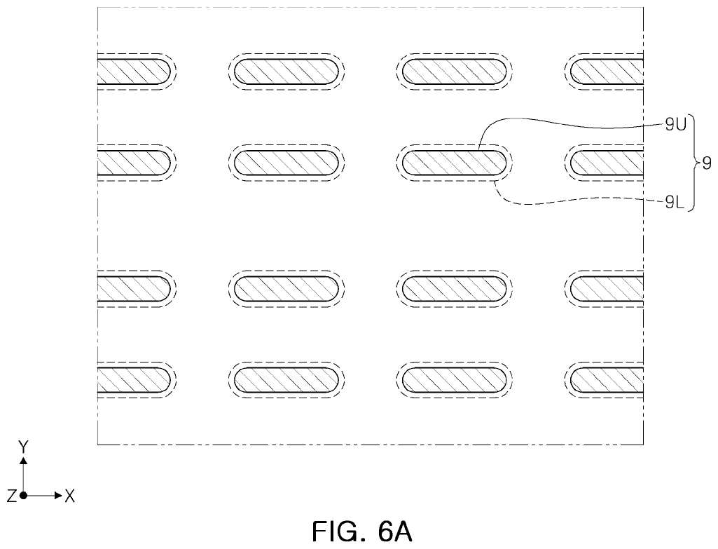

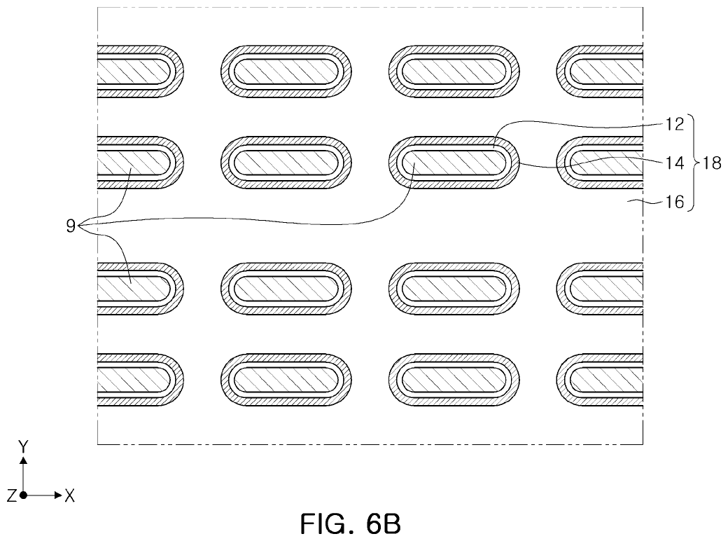

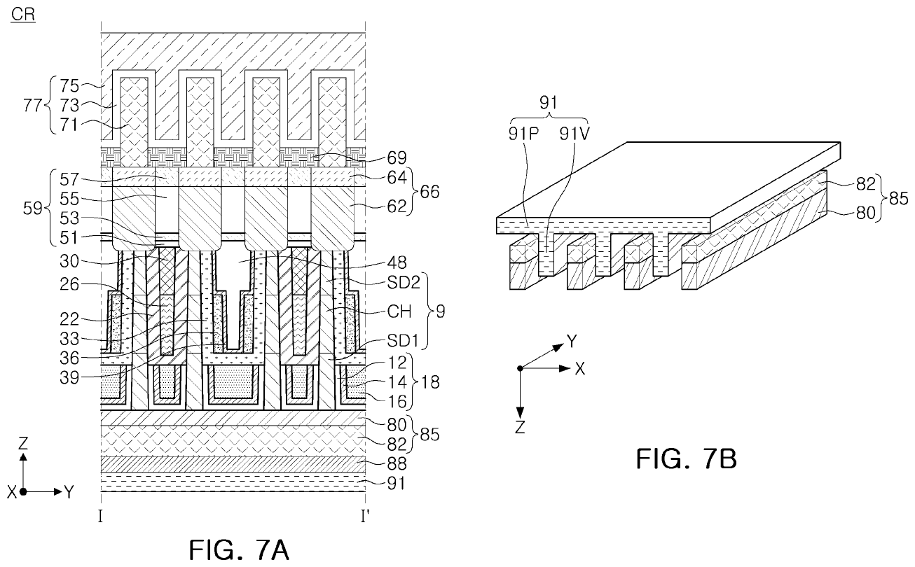

First, with reference to FIGS. 5A, 5B, 6A, 6B, 7A and 7B, some examples of the memory region CR of the semiconductor device 1 will be described. In FIGS. 5A to 7B, FIG. 5A is a plan view illustrating the memory region CR of the semiconductor device 1, FIG. 5B is a partially enlarged view of a region indicated by ‘A’ in FIG. 5A, and FIG. 6A is a plan view illustrating lower surfaces 9L and upper surfaces 9U of active patterns 9 of the memory region CR of the semiconductor device 1, FIG. 6B is a plan view illustrating active patterns 9 and a buffer insulating structure 18 of the memory region CR of the semiconductor device 1, FIG. 7A is a cross-sectional view illustrating a region taken along the line I-I′ of FIG. 5A, and FIG. 7B is a conceptual perspective view illustrating bit lines 85 and a bit line shield structure 91 of the memory region CR of the semiconductor device 1.

Referring to FIGS. 5A to 7B along with FIGS. 1 to 3, the memory region CR may include active patterns 9, word lines 36, and back gate electrodes 26.

Each of the active patterns 9 may include a first source/drain region SD1, a second source/drain region SD2 disposed at a level higher than a level of the first source/drain region SD1, and a channel region CH between the first and second source/drain regions SD1 and SD2. Each of the active patterns 9 may have an upper surface 9U (see FIG. 6A) having a width smaller than a width of a lower surface 9L (see FIG. 6A). Each of the active patterns 9 may have an inclined side surface so that the width of the lower surface 9L (see FIG. 6A) is smaller than the width of the upper surface 9U (see FIG. 6A). A width of the first source/drain region SD1 may be greater than a width of the second source/drain region SD2. The active patterns 9 may be formed of a semiconductor material such as single crystal silicon.

Each of the above active patterns 9 may have a bar shape extending in the first horizontal direction (X-direction). The active patterns 9 may be arranged in the first horizontal direction (X-direction) and a second horizontal direction (Y-direction), perpendicular to the first horizontal direction (X-direction).

The word lines 36 may be the word lines WL in FIG. 2. The back gate electrodes 26 may be the back gate lines BG in FIG. 2. In some example embodiments, the word lines 36 may be referred to as first gate electrodes, and the back gate electrodes 26 may be referred to as second gate electrodes. The word lines 36 may be spaced apart from each other in the second horizontal direction (Y-direction). The back gate electrodes 26 may be spaced apart from each other in the second horizontal direction (Y-direction).

The back gate electrodes 26 may include a first back gate electrode 26a and a second back gate electrode 26b, adjacent to each other and parallel to each other. The word lines 36 may include a first word line 36a and a second word line 36b, adjacent to each other and parallel to each other. A pair of the first and second word lines 36a and 36b may be disposed between the first and second back gate electrodes 26a and 26b.

In a plan view, the active patterns 9 may be disposed between one back gate electrode 26 and one word line 36, adjacent to each other in the second horizontal direction (Y-direction), among the back gate electrode 26 and the word lines 36. The channel regions CH of the active patterns 9 may be disposed between a back gate electrode 26 and a word lines 36, adjacent to each other in the second horizontal direction (Y-direction), among the back gate electrode 26 and the word lines 36. The active patterns 9 may not be disposed between a pair of word lines 36a and 36b, adjacent to each other in the second horizontal direction (Y-direction), among the word lines 36.

The first back gate electrode 26a and the first word line 36a, among the back gate electrodes 26 and the word lines 36, may be adjacent to each other. The active patterns 9 may include a first active pattern 9a and a second active pattern 9b disposed between the first back gate electrode 26a and the first word line 36a, and arranged sequentially in the first horizontal direction (X-direction) and disposed adjacently to each other.

The first active pattern 9a may have a first-first side surface S1_9a and a first-second side surface S2-9a opposing each other in the second horizontal direction (Y-direction), and a first-third side surface S3_9a and a first-fourth side surface S4_9a opposing each other in the first horizontal direction (X-direction). The first-third side surface S3_9a and the first-fourth side surface S4_9a may have a convex shape in an outward direction. Here, the outward direction may be a direction away from a center between the first-third side surface S3_9a and the first-fourth side surface S4_9a. The second active pattern 9b may have a second-first side surface S1_9b and a first-second side surface S2-9b opposing each other in the second horizontal direction (Y-direction), and a second-third side surface S3_9b and a second-fourth side surface S4_9b opposing each other in the first horizontal direction (X-direction). The second-third side surface S3_9b and the second-fourth side surface S4_9b may have a convex shape in the outward direction. Here, the outward direction may be a direction away from a center between the second-third side surface S3_9b and the second-fourth side surface S4_9b. The first back gate electrode 26a may include a line portion 26_L having first regions facing the first and second active patterns 9a and 9b and a second region between the first regions, a first protrusion 26_P1 protruding from the second region of the line portion 26_L in a direction toward the first word line 36a, and a second protrusion 26_P2 protruding from the second region of the line portion 26_L in a direction away from the word line 36. Each of the first and second protrusions 26_P1 and 26_P2 may have a width that gradually decreases in a direction away from the line portion 26_L.

The first word line 36a may include first and second portions 36_1 and 36_2 facing the first and second active patterns 9a and 9b and a bent portion 26_3 bent in a direction from the first and second portions 36_1 and 36_2 toward the first protrusion 26_P1 of the first back gate electrode 26a.

The memory region CR may further include back gate capping patterns 30 disposed on the back gate electrodes 26. The back gate capping patterns 30 may be formed of an insulating material.

The memory region CR may further include gate dielectric structures 22 and 33. The gate dielectric structures 22 and 33 may include a back gate dielectric layer 22 and a cell gate dielectric layer 33. The back gate dielectric layer 22 may be referred to as a first gate dielectric layer, and the cell gate dielectric layer 33 may be referred to as a second gate dielectric layer.

The back gate dielectric layer 22 may cover side surfaces of the back gate electrode 26 and the back gate capping pattern 30, which are sequentially stacked, and may cover a lower surface of the back gate electrode 26. The cell gate dielectric layer 33 may be disposed between the word lines 36 and the active patterns 9 adjacent to each other and extends upwardly, and may cover lower surfaces of the word lines 36.

A portion of the back gate dielectric layer 22 may extend between the first-fourth side surface S4_9a of the first active pattern 9a and the second-third side surface S3_9b of the second active pattern 9b. A portion of the cell gate dielectric layer 33 may extend between the first-fourth side surface S4_9a of the first active pattern 9a and the second-third side surface S3_9b of the second active pattern 9b. Accordingly, a portion of the back gate dielectric layer 22 and a portion of the cell gate dielectric layer 33 may be disposed between the first-fourth side surface S4_9a of the first active pattern 9a and the second-third side surface S3_9b of the second active pattern 9b.

The memory region CR may further include a buffer insulating structure 18. The buffer insulating structure 18 may be disposed below the gate dielectric structure 22 and 33, the back gate electrodes 26 and the word lines 36, and may surround side surfaces of lower regions of each of the active patterns 9. For example, the buffer insulating structure 18 may surround side surfaces of the first source/drain regions SD1 of the active patterns 9.

The buffer insulating structure 18 may include a buffer pattern 16 and a first buffer liner 14 covering a side surface and a lower surface of the buffer pattern 16. In a plan view, the first buffer liner 14 may surround the side surface of the lower region of the first active pattern 9a in a ring shape, and may surround the side surface of the lower region of the second active pattern 9b in the ring shape.

The buffer insulating structure 18 may further include a second buffer liner 12 between the side surfaces of the lower regions of each of the first and second active patterns 9a and 9b and the first buffer liner 14. The second buffer liner 12 may extend below a lower surface of the first buffer liner 14.

A material of the first buffer liner 14 may be different from a material of the second buffer liner 12 and a material of the buffer pattern 16. For example, the material of the first buffer liner 14 may include a nitride, and the material of the second buffer liner 12 and the material of the buffer pattern 16 may include an oxide. However, example embodiments are not limited thereto.

The memory region CR may further include an insulating pattern 48 disposed between the word lines 36 adjacent to each other and extending upwardly, and covering upper surfaces of the word lines 36, and an insulating liner 39 covering side surfaces and lower surfaces of the insulating pattern 48. A material of the insulating liner 39 may be different from a material of the insulating pattern 48. For example, the insulating liner 39 may include a nitride, and the insulating pattern 48 may include an oxide. However, example embodiments are not limited thereto.

The memory region CR may further include bit lines 85. The bit lines 85 may be the bit lines BL in FIG. 2.

Each of the bit lines 85 may include a first conductive layer 80 connected to the first source/drain regions SD1 of the active patterns 9 and a second conductive layer 82 below the first conductive layer 80. The first conductive layer 80 may include doped polysilicon, and the second conductive layer 82 may include at least one of a metal, a metal nitride, and a metal semiconductor compound. However, example embodiments are not limited thereto.

The memory region CR may further include a bit line shield structure 91 and an insulating layer 88 between the bit line shield structure 91 and the bit lines 85. The bit line shield structure 91 may be formed of a conductive material. The bit line shield structure 91 may include vertical portions 91V (see FIG. 7b) disposed between the bit lines 85 and plate portions 91P (see FIG. 7b) extending from the vertical portions 91V and vertically overlapping the bit lines 85.

The memory region CR may further include an insulating structure 59 disposed on the active patterns 9, the insulating pattern 48 and the back gate capping pattern 30. The insulating structure 59 may include a first insulating layer 51, a second insulating layer 53, a third insulating layer 55, and a fourth insulating layer 57, which are sequentially stacked. A material of the second insulating layer 53 may be different from materials of the first and third insulating layers 51 and 55. For example, the material of the second insulating layer 53 may include a nitride, and the materials of the first and third insulating layers 51 and 55 may include an oxide. However, example embodiments are not limited thereto. A thickness of the third insulating layer 55 may be greater than thicknesses of each of the first, second and fourth insulating layers 51, 53 and 57.

The memory region CR may further include pad structures 66 penetrating through the insulating structure 59. Each of the pad structures 66 may include a first pad pattern 62 and a second pad pattern 64 on the first pad pattern 62. The first pad pattern 62 may include doped polysilicon. The second pad pattern 64 may include at least one of a metal, a metal nitride, and a metal-semiconductor compound. However, example embodiments are not limited thereto. The first pad patterns 62 of the pad structures 66 may be connected to the second source/drain regions SD2 of the active patterns 9.

In some example embodiments, vertical central axes of the pad structures 66 may not be vertically aligned with vertical central axes of the active patterns 9.

The memory region CR may further include an insulating etch stop layer 69 and a data storage structure 77. The insulating etch stop layer 69 may be disposed on the insulating structure 59 and the pad structures 66. The data storage structure 77 may include first electrodes 71 penetrating through the insulating etch stop layer 69, connected to the pad structures 66 and extending upwardly, a dielectric layer 73 disposed on the insulating etch stop layer 69 and the first electrodes 71, and a second electrode 75 on the dielectric layer 73. The data storage structure 77 may be the data storage structure DS in FIG. 2. For example, the data storage structure 77 may be a cell capacitor that may store information in a memory device such as a DRAM device.

In some example embodiments, the cell transistor cTR (see FIG. 2) may include the first source/drain region SD1, the channel region CH, the second source/drain region SD2, the word line 36 (WL) facing the channel region CH, and a cell gate dielectric layer 33 between the word line 36 (WL) and the channel region CH.

In some example embodiments, the back gate electrode 26 (BG) may reduce, minimize, and/or prevent a threshold voltage of the cell transistor cTR from fluctuating because charges, for example, holes, are accumulated in a floating body of the channel region CH when the cell transistor cTR (see FIG. 2) operates. Since the back gate electrode 26 (BG) may allow the cell transistor cTR to operate stably, the performance of the semiconductor device 1 may be improved.

In some example embodiments, each of the active patterns 9 may have a lower surface having a width greater than that of an upper surface thereof. Since the active patterns 9 having such a shape may reduce and/or prevent the collapse or deformation of the active patterns 9, this may reduce and/or prevent defects of the semiconductor element 1 and/or improve the productivity of the semiconductor element 1.

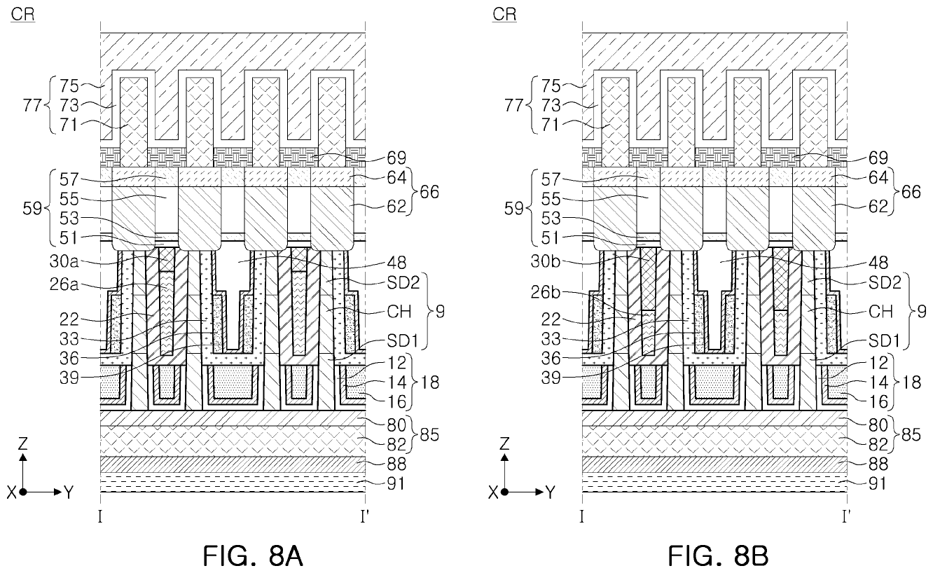

Next, referring to FIGS. 8A to 18, various examples of the memory region CR of the semiconductor element 1 according to some example embodiments of the present disclosure will be described. FIGS. 8A, 8B, 9A, 9B, 9C, 10A, 10B, 10C, 11A, 11B, 11C, 12A, 12B, 13A, 13B, 13C, 14, 15A, 15B, 16, 17 and 18 are cross-sectional views illustrating examples of cross-sectional structure I-I′ of FIG. 7A, to illustrate various examples of semiconductor devices according to some example embodiments of the present disclosure.

In some example embodiments, referring to FIG. 8A, the back gate electrode 26 (see FIG. 7a) disposed on substantially the same level as an upper surface of the word line 36 in FIG. 7A may be replaced with a first back gate electrode 26a having an upper surface disposed on a different level from the upper surface of the word line 36, and the back gate capping pattern 30 (see FIG. 7A) may be replaced with a back gate capping pattern 30a disposed on the first back gate electrode 26a.

In some example embodiments, referring to FIG. 8B, the back gate electrode 26 (see FIG. 7A) in FIG. 7A may be replaced with a second back gate electrode 26b having an upper surface disposed at a level lower than that of the upper surface of the word line 36, and the back gate capping pattern 30 (see FIG. 7A) may be replaced with a back gate capping pattern 30b disposed on the second back gate electrode 26b.

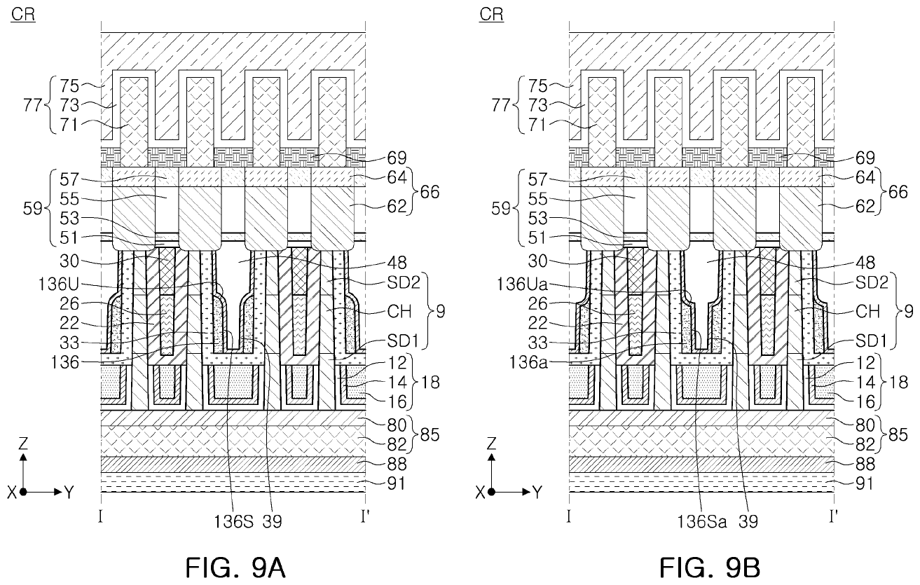

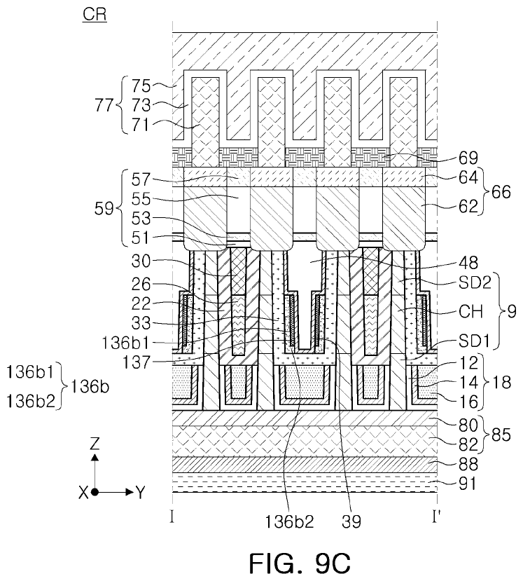

In some example embodiments, referring to FIG. 9A, the word line 36 (see FIG. 7A) having a substantially flat upper surface in FIG. 7A may be replaced with a word line 136 having an upper surface 136U which is gradually lowered and has a bent surface in a direction away from the adjacent active pattern 9. A side surface 136S of the word line 136 may be parallel to the active pattern 9, and the upper surface 136U of the word line 136 may extend from the side surface 136S and have an upwardly convex shape.

In some example embodiments, referring to FIG. 9B, the word line 36 (see FIG. 7A) having a substantially flat upper surface in FIG. 7A may be replaced with a word line 136a having an upper surface 136Ua formed to be concave while being lowered in a direction away from the adjacent active pattern 9 and a side surface 136Sa parallel to the active pattern 9.

In some example embodiments, referring to FIG. 9C, the word line 36 (see FIG. 7A) described above may be replaced with a word line 136b including a vertical portion 136b1, parallel to a side surface of the adjacent active pattern 9, and a horizontal portion 136b2 extending from a lower region of the vertical portion 136b1 in a direction away from the active pattern 9. An insulating pattern 137 in contact with contact the vertical portion 136b1 may be disposed on the horizontal portion 136b2 of the active pattern 9.

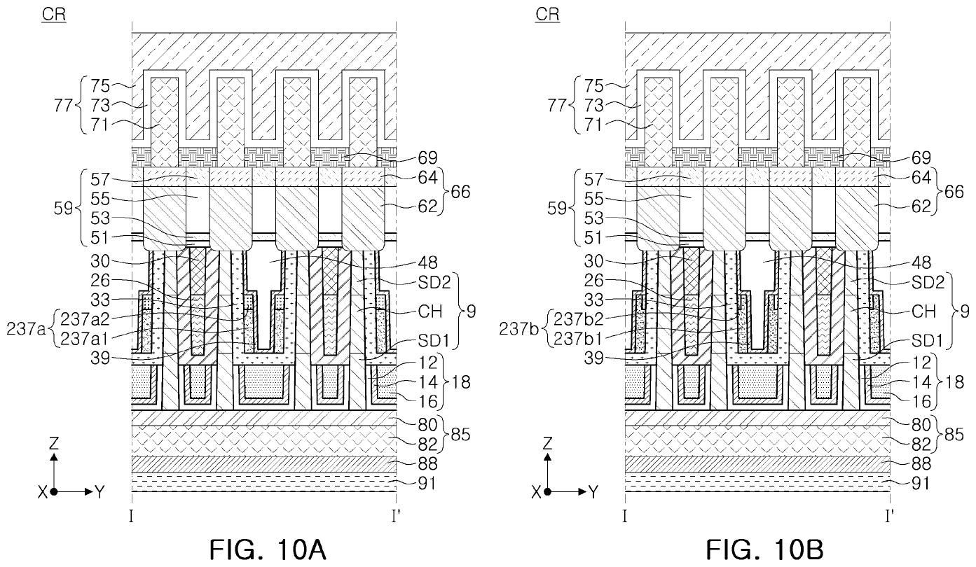

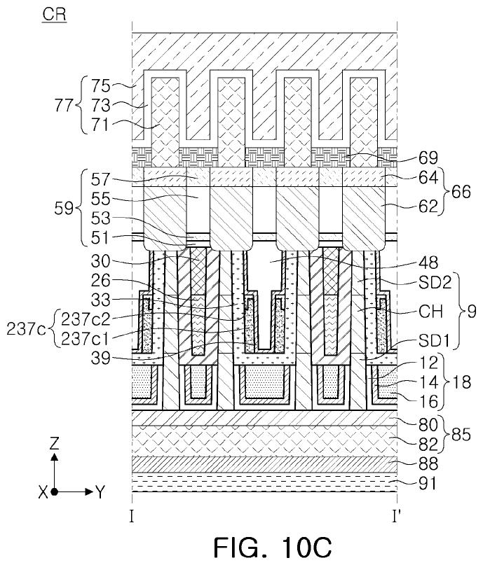

In some example embodiments, referring to FIG. 10A, the word line 36 (see FIG. 7A) described above may include a single conductive layer, and the word line 36 (see FIG. 7A) may be replaced with a word line 237a including two or more conductive layers 237a1 and 237a2. The word line 237a may include a first conductive layer 237a1 and a second conductive layer 237a2 on the first conductive layer 237a1. The second conductive layer 237a2 may be a different material from the first conductive layer 237a1. The second conductive layer 237a2 may be a work function control layer (e.g., TiN, TaN, or TiAlN) for controlling the threshold voltage of the cell transistor CTR (see FIG. 2), and the first conductive layer 237a1 may be a conductive layer (e.g., W, Mo, or the like) having relatively low resistivity formed to lower entire resistance of the gate electrode of the cell transistor CTR (see FIG. 2), i.e., the word line 237a. However, example embodiments are not limited thereto. In the word line 237a, a vertical thickness of the second conductive layer 237a2 may be lower than a vertical thickness of the first conductive layer 237al.

In some example embodiments, referring to FIG. 10B, the word line 237a (see FIG. 10A) in FIG. 10A may be replaced with a word line 237b as in FIG. 10B. The word line 237b may include a first conductive layer 237b1 and a second conductive layer 237b2 disposed between an upper region of the first conductive layer 237b1 and the cell gate dielectric layer 33. As illustrated in FIG. 10A, the first conductive layer 237b1 may be a conductive layer having relatively low resistivity, and the second conductive layer 237b2 may be a work function control layer.

In some example embodiments, referring to FIG. 10C, the word line 237b (see FIG. 10b) in FIG. 10B may be replaced with a word line 237c as in FIG. 10C. The word line 237c may include a first conductive layer 237cl, and a second conductive layer 237c2 disposed between an upper region of the first conductive layer 237cl and the cell gate dielectric layer 33 and covering an upper surface of the first conductive layer 237cl. As illustrated in FIG. 10A, the first conductive layer 237cl may be a conductive layer having relatively low resistivity, and the second conductive layer 237c2 may be a work function control layer.

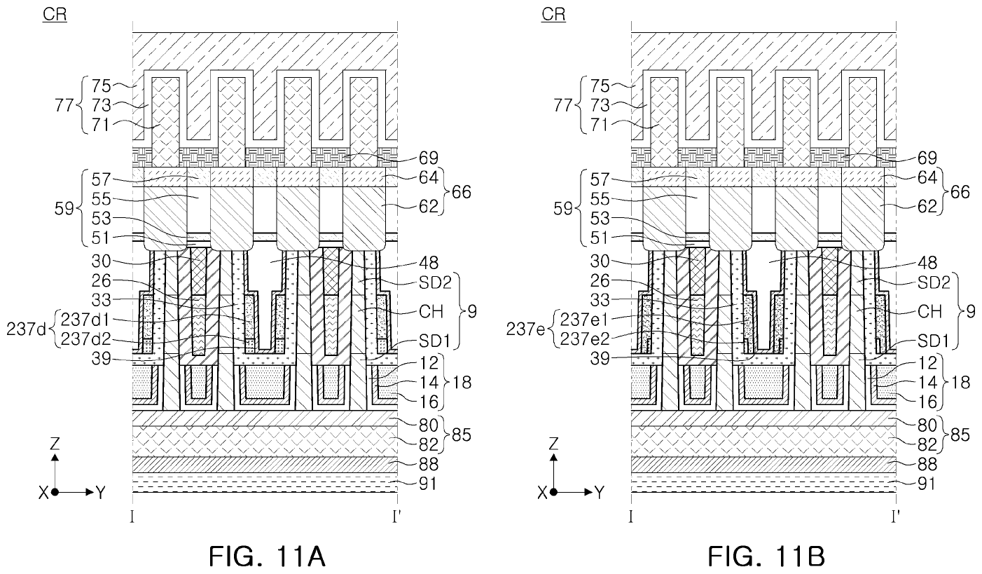

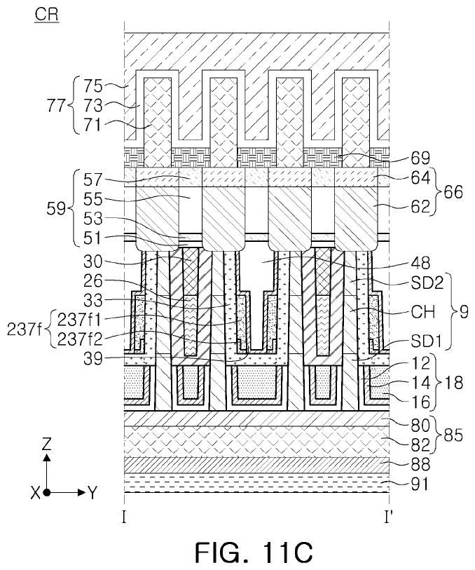

In some example embodiments, referring to FIG. 11A, the word line 237a (see FIG. 10A) in FIG. 10A may be replaced with a word line 237d as in FIG. 10D. The word line 237d may include a first conductive layer 237d1 and a second conductive layer 237d2 below the first conductive layer 237d1. A vertical thickness of the second conductive layer 237d2 may be lower than a vertical thickness of the first conductive layer 237d1. As illustrated in FIG. 10A, the first conductive layer 237d1 may be a conductive layer having relatively low resistivity, and the second conductive layer 237d2 may be a work function control layer.

In some example embodiments, referring to FIG. 11B, the word line 237d (see FIG. 11A) in FIG. 11A may be replaced with a word line 237e as in FIG. 11B. The word line 237e may include a first conductive layer 237e1 and a second conductive layer 237e2 disposed between a lower region of the first conductive layer 237e1 and the cell gate dielectric layer 33. As illustrated in FIG. 10A, the first conductive layer 237e1 may be a conductive layer having relatively low resistivity, and the second conductive layer 237e2 may be a work function control layer.

In some example embodiments, referring to FIG. 11C, the word line 237e (see FIG. 11B) in FIG. 11b may be replaced with a word line 237f as in FIG. 11C. The word line 237f may include a first conductive layer 237f1 and a second conductive layer 237f2 disposed between a lower region of the first conductive layer 237f1 and the cell gate dielectric layer 33 and covering a lower surface of the first conductive layer 237f1. As illustrated in FIG. 10A, the first conductive layer 237f1 may be a conductive layer having relatively low resistivity, and the second conductive layer 237f2 may be a work function control layer.

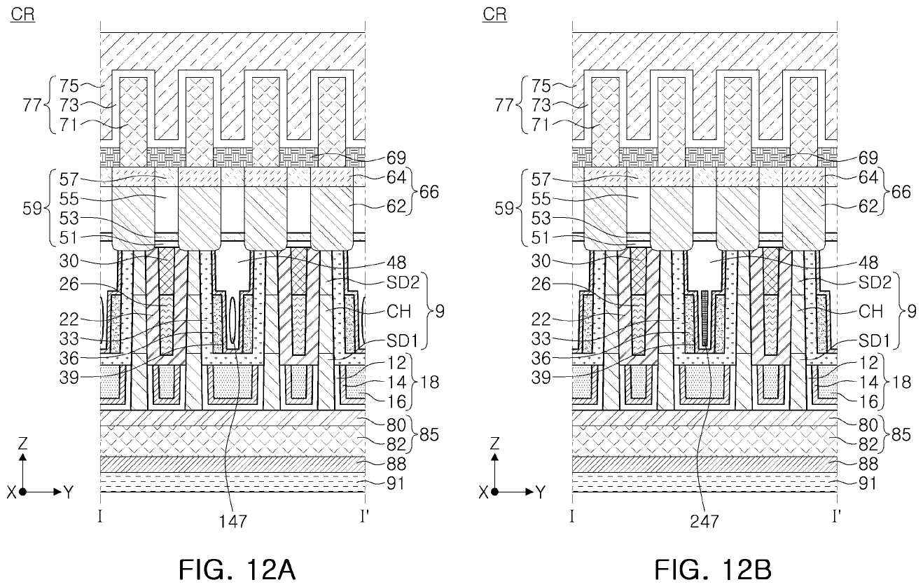

In some example embodiments, referring to FIG. 12A, an air gap 147 may be disposed in the insulating pattern 48 located between the word lines 36 adjacent to each other. The air gap 147 may improve the signal transmission speed of the word lines 36.

In some example embodiments, referring to FIG. 12B, a conductive shield line 247 may be disposed in the insulating pattern 48 located between the word lines 36 adjacent to each other. The conductive shield line 247 may improve the signal transmission speed of the word lines 36.

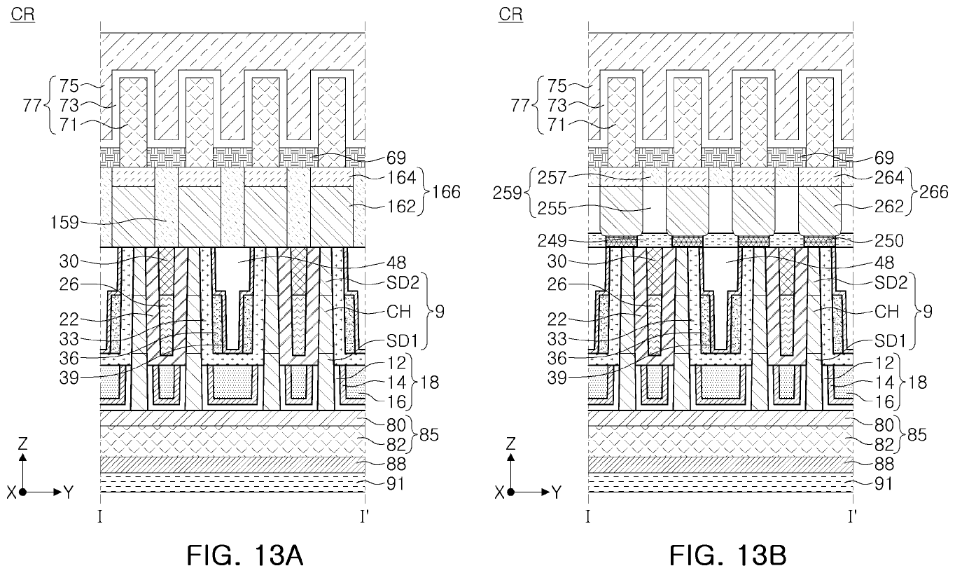

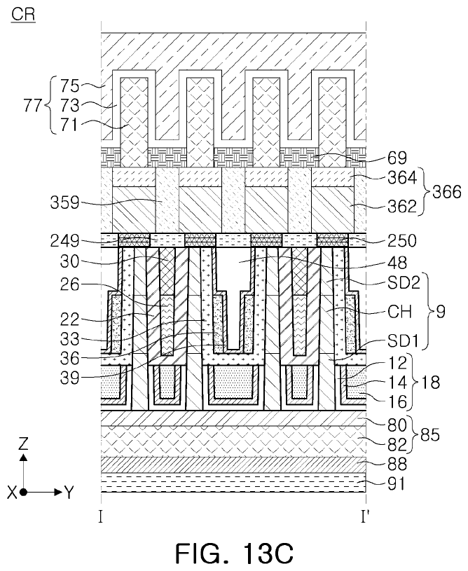

In some example embodiments, referring to FIG. 13A, the insulating structure 59 (see FIG. 7A) described above may be replaced with an insulating structure 159 as in FIG. 13A, and the pad structures 66 (see FIG. 7A) described above may be replaced with pad structures 166 as in FIG. 13A. The pad structures 66 (see FIG. 7A) described above may have lower surfaces formed to be downwardly convex, and the pad structures 166 in FIG. 13A may have substantially flat lower surfaces. The insulating structure 159 may surround side surfaces of the pad structures 166. Each of the pad structures 166 may include a first pad pattern 162 and a second pad pattern 164 on the first pad pattern 162.

In some example embodiments, referring to FIG. 13B, the memory region CR may further include extended source/drain patterns 250 connected to the second source/drain regions SD2 of the active patterns 9 and an insulating pattern 249 on side surfaces of the extended source/drain patterns 250. The extended source/drain patterns 250 may be formed of a doped polysilicon layer or a doped epitaxial layer. Vertical central axes of the extended source/drain patterns 250 may not be aligned with vertical central axes of the active patterns 9.

The insulating structure 59 (see FIG. 7A) described above may be replaced with an insulating structure 259 as in FIG. 13B, and the pad structures 66 (see FIG. 7A) described above may be replaced with pad structures 266 as in FIG. 13B. The insulating structure 259 may surround side surfaces of the pad structures 266. The insulating structure 259 may include a first insulating layer 255 and a second insulating layer 257 on the first insulating layer 255. Each of the pad structures 266 may include a first pad pattern 262 and a second pad pattern 264 on the first pad pattern 262. The pad structures 266 may be disposed on the extended source/drain patterns 250.

In some example embodiments, referring to FIG. 13C, the insulating structure 259 (see FIG. 13B) described above may be replaced with an insulating structure 359 as in FIG. 13C, and the pad structures 266 (see FIG. 13B) described above may be replaced with pad structures 166 as in FIG. 13A. The pad structures 266 (see FIG. 13B) described above may have lower surfaces formed to be downwardly convex, and the pad structures 366 in FIG. 13C may have substantially flat lower surfaces. The insulating structure 359 may surround side surfaces of the pad structures 366. Each of the pad structures 366 may include a first pad pattern 362 and a second pad pattern 364 on the first pad pattern 362.

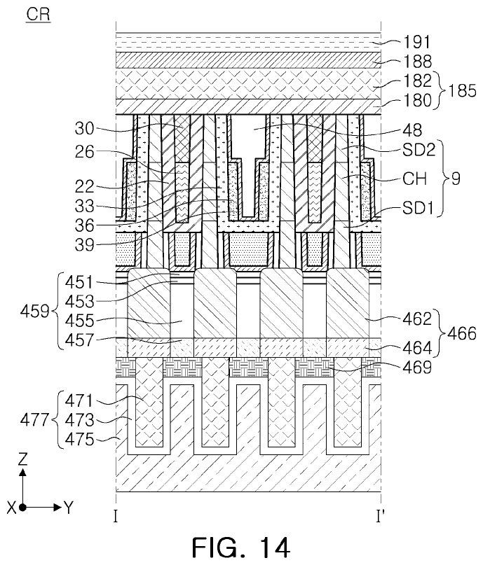

In some example embodiments, referring to FIG. 14, the bit lines 85, the insulating layer 88, and the bit line shield structure 91 in FIG. 7A may be replaced with bit lines 185, an insulating layer 188, and a bit line shield structure 191, which are disposed on the second source/drain regions SD2 of the active patterns 9, and the insulating structure 59, the pad structures 66, the etch stop layer 69 and the data storage structure 77 in FIG. 7A may be replaced with an insulating structure 459, pad structures 466, an etch stop layer 469, and a data storage structure 477, which are disposed below the first source/drain regions SD1 of the active patterns 9.

Each of the bit lines 185 may include a first conductive layer 180 connected to the second source/drain regions SD2 of the active patterns 9 and a second conductive layer 182 on the first conductive layer 180. The first conductive layer 180 may include doped polysilicon or a doped epitaxial semiconductor, and the second conductive layer 182 may include at least one of a metal, a metal nitride, and a metal semiconductor compound. However, example embodiments are not limited thereto. The bit line shield structure 191 may cover upper surfaces of the bit lines 185 and may extend between side surfaces of the bit lines 185. The insulating layer 188 may be disposed between the bit line shield structure 191 and the bit lines 185.

The insulating structure 459 may include a first insulating layer 451, a second insulating layer 453, a third insulating layer 455, and a fourth insulating layer 457, which are sequentially stacked in a downward direction. A material of the second insulating layer 453 may be different from materials of the first and third insulating layers 451 and 455.

Each of the pad structures 466 may include a first pad pattern 462 and a second pad pattern 464 below the first pad pattern 462. The first pad pattern 462 may include doped polysilicon. The second pad pattern 464 may include at least one of a metal, a metal nitride, and a metal-semiconductor compound. However, example embodiments are not limited thereto. The first pad patterns 462 of the pad structures 466 may be connected to the first source/drain regions SD1 of the active patterns 9.

The insulating etch stop layer 469 may be disposed below the insulating structure 459 and the pad structures 466. The data storage structure 477 may include first electrodes 471 penetrating through the insulating etch stop layer 469 and connected to the pad structures 466 and extending downwardly, a dielectric layer 473 disposed on the insulating etch stop layer 469 and the first electrodes 471, and a second electrode 475 on the dielectric layer 473.

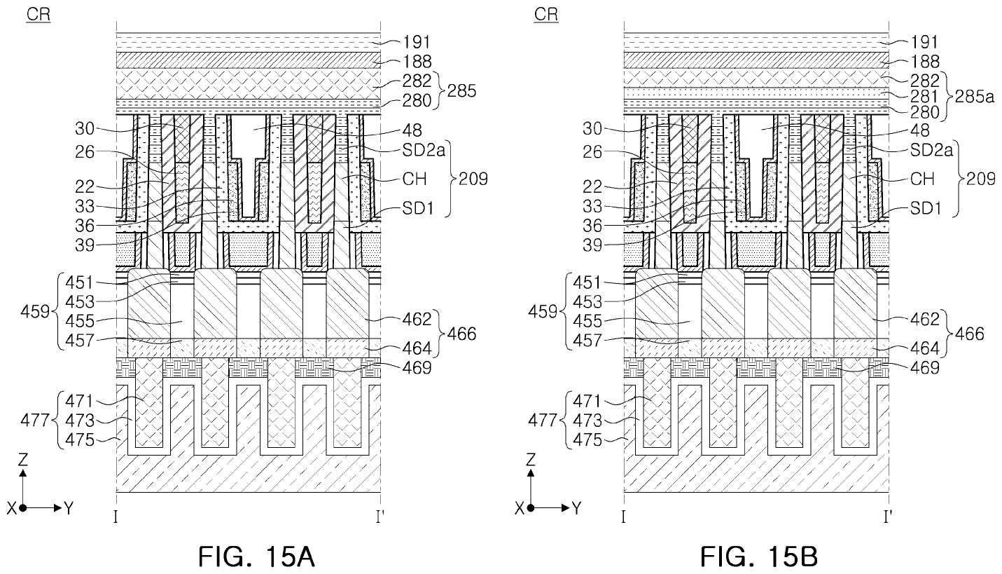

In some example embodiments, referring to FIG. 15A, each of the above-described active patterns 9 may be replaced with active patterns 209 including two or more semiconductor materials. For example, each of the active patterns 209 may include a first semiconductor material layer SD1 (CH) formed of a first semiconductor material and a second semiconductor material layer SD2a on the first semiconductor material layer SD1 (CH).

The first semiconductor material layer SD1 (CH) may include a semiconductor material such as single crystal silicon, and the second semiconductor material layer SD2a may include a semiconductor material different from the first semiconductor material layer SD1 (CH), for example, an epitaxial SiGe material. However, example embodiments are not limited thereto.

The first source/drain region SD1 and the channel region CH described above may be formed in the first semiconductor material layer SD1 (CH).

The second source/drain region SD2 described above may be formed in the second semiconductor material layer SD2a.

The second semiconductor material layer SD2a that may include an epitaxial SiGe material may control a floating body effect in the channel region CH of the cell transistor cTR described above, thereby improving the performance of the cell transistor cTR.

The second semiconductor material layer SD2a that may include an epitaxial SiGe material and the first conductive layer 280 of the bit line 285 may be formed integrally. For example, the second semiconductor material layer SD2a and the first conductive layer 280 may include a continuously connected epitaxial SiGe material layer. However, example embodiments are not limited thereto.

In some example embodiments, referring to FIG. 15b, the bit line 285 (see FIG. 15A) illustrated in FIG. 15a may be replaced with a bit line 285a further including a third conductive layer 281 between the first conductive layer 280 and the second conductive layer 282. The third conductive layer 281 may include doped polysilicon. However, example embodiments are not limited thereto.

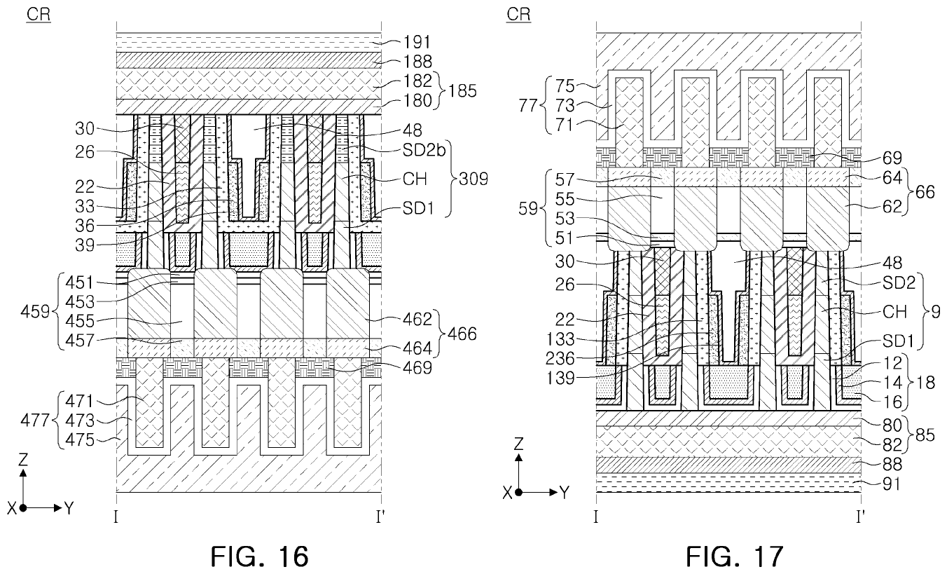

In some example embodiments, referring to FIG. 16, each of the active patterns 9 described above may be replaced with active patterns 309 including two or more semiconductor materials. For example, each of the active patterns 309 described above may include a first semiconductor material layer SD1 (CH) formed of a first semiconductor material and a second semiconductor material layer SD2b on the first semiconductor material layer SD1 (CH).

The second semiconductor material layer SD2a may be formed of a different material from the first conductive layer 180 of the bit line 185.

The first semiconductor material layer SD1 (CH) may include a semiconductor material such as single crystal silicon, and the second semiconductor material layer SD2b may include a different semiconductor material from the first semiconductor material layer SD1 (CH), for example, an epitaxial SiGe material. The first source/drain region SD1 and the channel region CH described above may be formed in the first semiconductor material layer SD1 (CH). The second source/drain region SD2 described above may be formed in the second semiconductor material layer SD2b.

In some example embodiments, referring to FIG. 17, the cell gate dielectric layer 33 (see FIG. 7A), the word line 36 (see FIG. 7A), and the insulating liner 39 (see FIG. 7A) described above may be replaced with a cell gate dielectric layer 133 and a word line 236 and an insulating liner 139 having lower surfaces in contact with an upper surface of the buffer insulating structure 18.

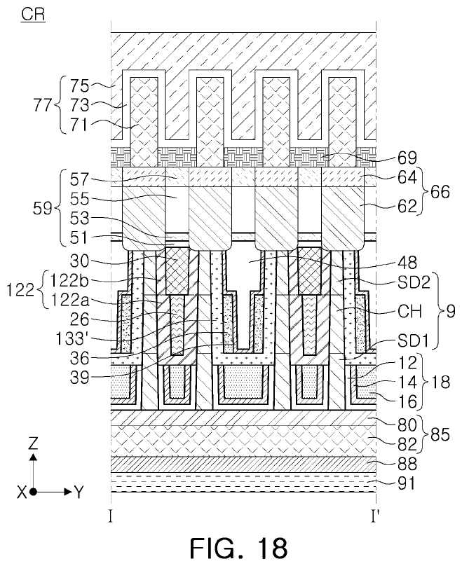

In some example embodiments, referring to FIG. 18, the back gate dielectric layer 22 (FIG. 7A) described above may be replaced with a back gate dielectric layer 122 including a first portion 122a in contact with the back gate electrode 26 and a second gate portion 122b having a thickness lower than that of the first portion 122a and in contact with a side surface of the back gate capping pattern 30.

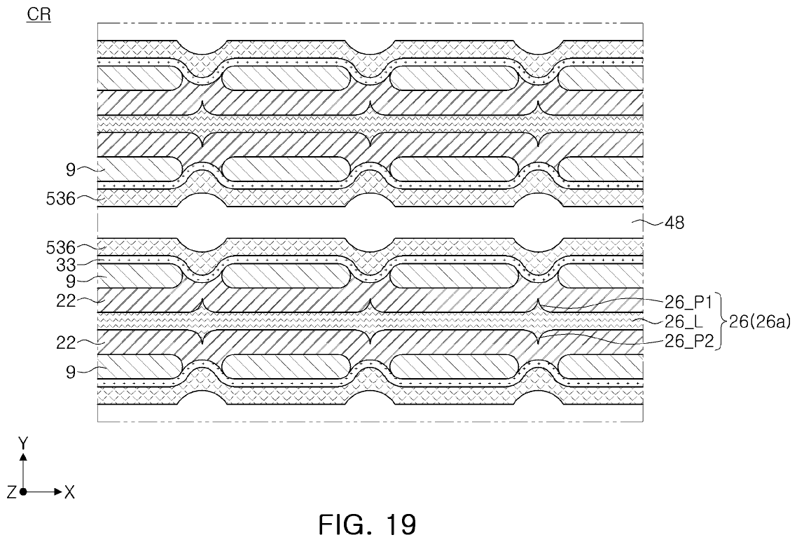

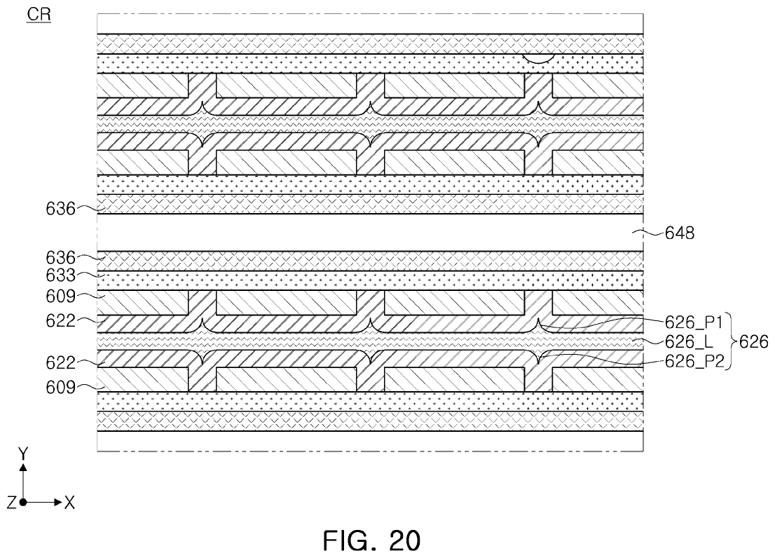

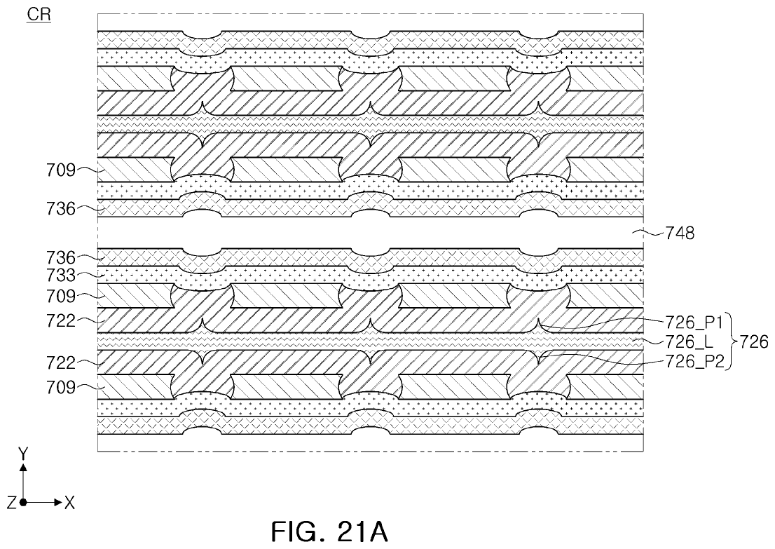

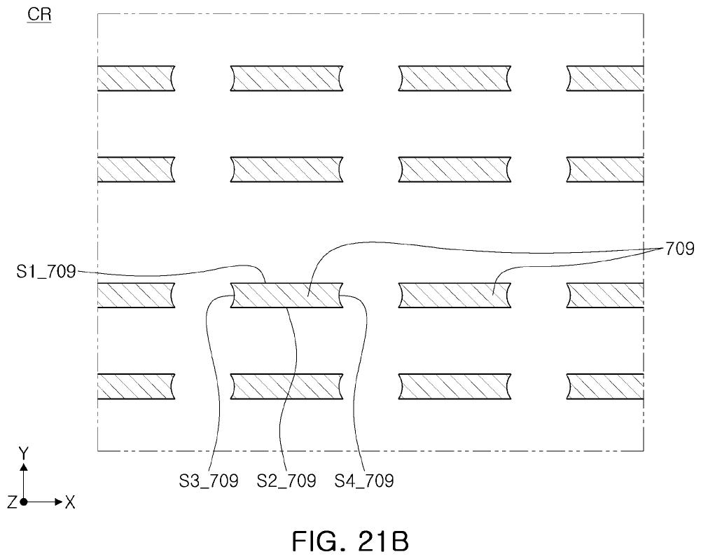

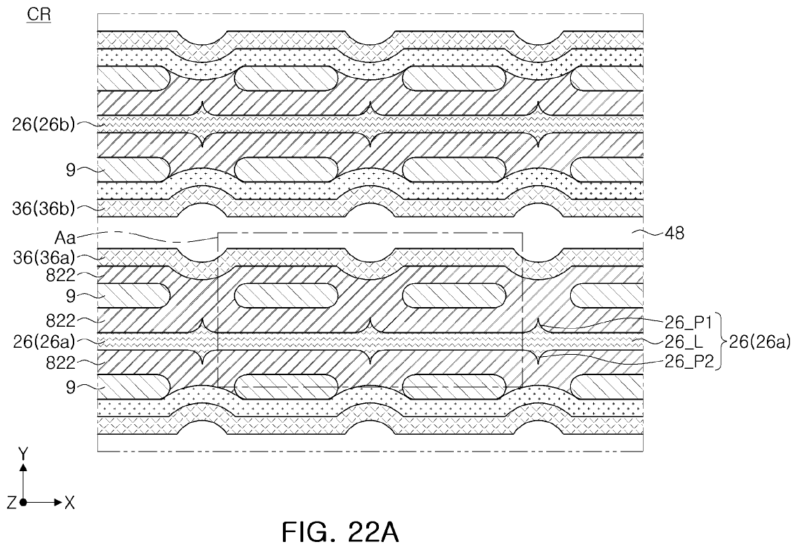

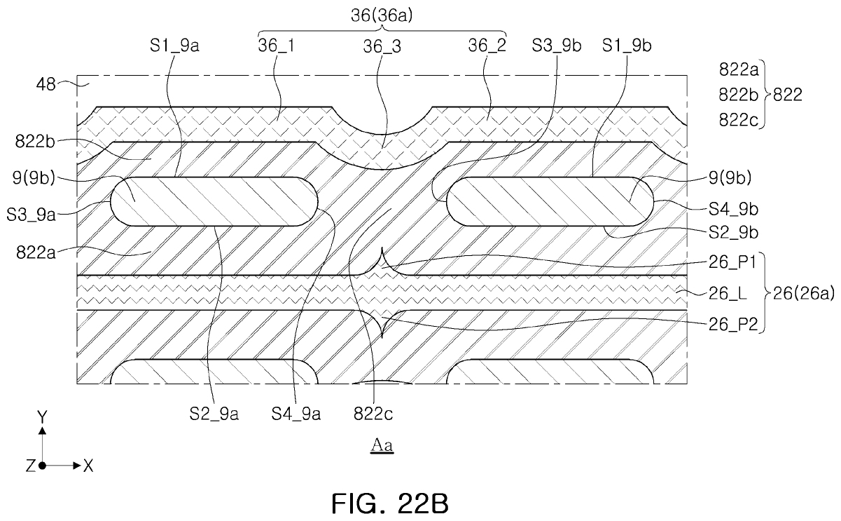

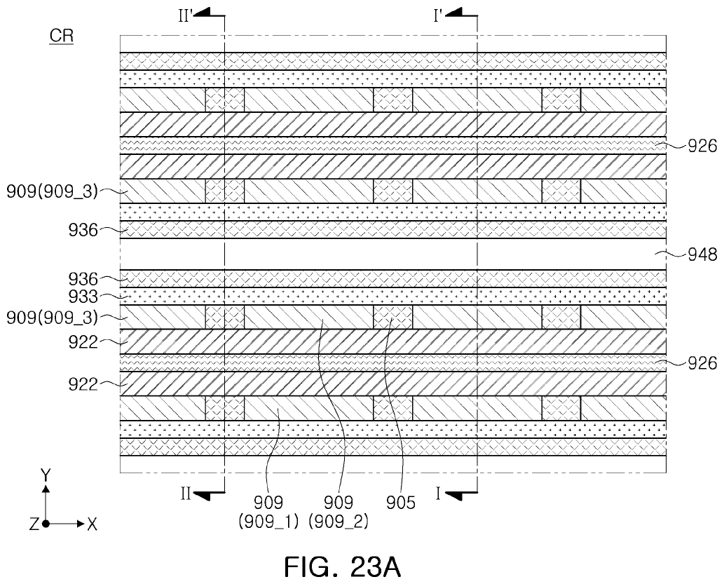

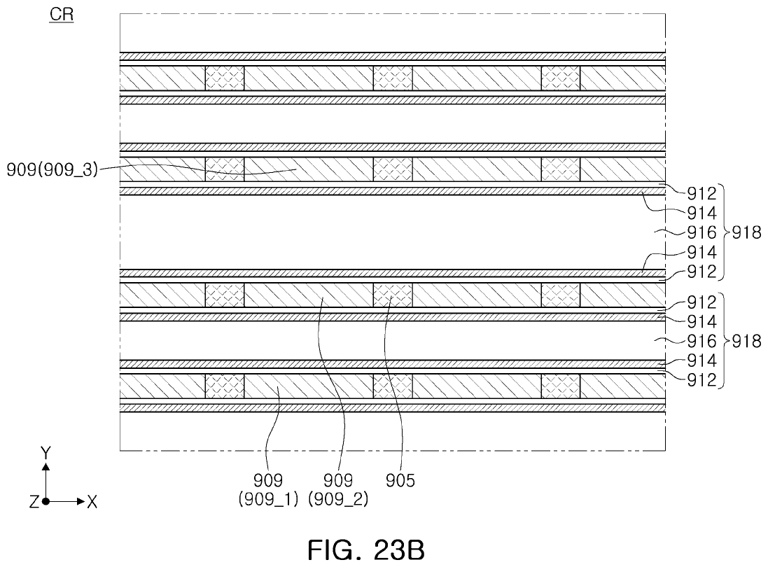

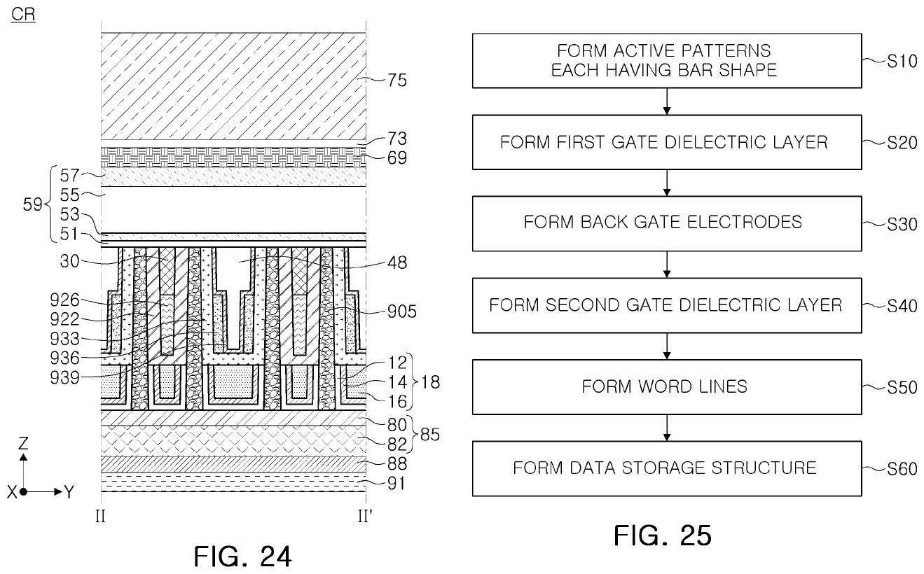

Next, referring to FIGS. 19 to 24, some examples of the memory region CR of the semiconductor device 1 according to some example embodiments of the present disclosure will be described. FIG. 19, FIG. 20, FIG. 21A, FIG. 22A and FIG. 23 are plan views each illustrating some examples of the plan view of FIG. 5A to illustrate various examples of the semiconductor device according to some example embodiments of the present disclosure, FIG. 21B is a plan view illustrating active patterns 709 of FIG. 21A, FIG. 22B is an enlarged partial view of a region indicated by ‘A’ of FIG. 22A, FIG. 23B is a plan view illustrating some elements in some example embodiments of FIG. 23A, and FIG. 24 is a cross-sectional view illustrating a region taken along line II-II′ of FIG. 23A.

In some example embodiments, referring to FIG. 19, the cell gate dielectric layer 33 (see FIG. 5A) described above may be replaced with a cell gate dielectric layer 533 having a reduced thickness, and the word line 36 (see FIG. 5A) described above may be replaced with a word line 536 having a bent portion extending between the cell active patterns 9 adjacent to each other in the first horizontal direction (X-direction).

In some example embodiments, referring to FIG. 20, the active pattern 9a described above may be replaced with an active pattern 609 having side surfaces opposing each other in the first horizontal direction (X-direction) and extending in a direction, parallel to the second horizontal direction (Y-direction). The back gate dielectric layer 22 (see FIG. 5A) described above may be replaced with a back gate dielectric layer 622 extending between the cell active patterns 9 adjacent to each other in the first horizontal direction (X-direction), and the cell gate dielectric layer 33 (see FIG. 5A) described above may be replaced with a cell gate dielectric layer 633 that does not extend between the cell active patterns 9 adjacent to each other in the first horizontal direction (X-direction). The back gate electrode 26 (FIG. 5A) described above may have a line portion 626_L extending in the first horizontal direction (X-direction) and protrusions 626_P1 and 626_P2 extending on both sides of the line portion 626_L and may be replaced with a back gate electrode 626 in contact with the back gate dielectric layer 622, and the word line 36 (see FIG. 5A) described above may be replaced with a word line 636 having a line shape extending in the first horizontal direction (X-direction) and contacting the cell gate dielectric layer 633. The insulating pattern 48 (see FIG. 5A) described above may be replaced with an insulating pattern 648 having a line shape extending in the first horizontal direction (X-direction).

In some example embodiments, referring to FIGS. 21A and 21B, each of the active patterns 9a described above may be replaced with active patterns 709 having a first side surface S1_709 and a second side surface S2-709 opposing each other in the second horizontal direction (Y-direction), and a third side surface S3_709 and a fourth side surface S4_709 opposing each other in the first horizontal direction (X-direction). In each of the active patterns 709, the third side surface S3_709 and the fourth side surface S4_709 may have a concave shape. The back gate dielectric layer 22 (see FIG. 5A) described above may be replaced with a back gate dielectric layer 722 extending between the cell active patterns 709 adjacent to each other in the first horizontal direction (X-direction), and the cell gate dielectric layer 33 (see FIG. 5A) described above may be replaced with a cell gate dielectric layer 733 extending between the third side surface S3_709 and the fourth side surface S4_709. The back gate electrode 26 (see FIG. 5A) described above may have a line portion 726_L extending in the first horizontal direction (X-direction) and protrusions 726_P1 and 726_P2 extending to both sides of the line portion 726_L, and may be replaced with a back gate electrode 726 in contact with the back gate dielectric layer 722, and the word line 36 (see FIG. 5A) described above may be replaced with a word line 736 having a line shape extending in the first horizontal direction (X-direction) and contacting the cell gate dielectric layer 733. The insulating pattern 48 (see FIG. 5A) described above may be replaced with an insulating pattern 748 adjacent to the word line 736.

In some example embodiments, referring to FIGS. 22A and 22B, when the gate dielectric structures 22 and 33 (see FIG. 5A) described above are continuously connected without a boundary, the gate dielectric structures 22 and 33 may be replaced with a gate dielectric structure 822 formed integrally.

The gate dielectric structure 822 may include first portions 822a disposed between the back gate electrode 26 and the first and second active patterns 9a and 9b, second portions 822b disposed between the word line 36 and the first and second active patterns 9a and 9b, and third portions 822c disposed between the first and second active patterns 9a and 9b. A thickness of each of the first portions 822a may be greater than a thickness of each of the second portions 822b.

In some example embodiments, referring to FIG. 23A, FIG. 23B and FIG. 24 together with FIG. 7A, a region indicated by line I-I′ in FIG. 23A may have the same cross-sectional structure as cross-sectional structure I-I′ of FIG. 7A. The active patterns 9 described above may be replaced with active patterns 909 having a rectangular shape. An insulating pillar 905 may be disposed between active patterns 909 adjacent to each other in the first horizontal direction (X-direction), among the active patterns 909.

The active patterns 909 may include first active patterns 909_1 arranged sequentially in the first horizontal direction (X-direction), second active patterns 909_2 spaced apart from the first active patterns 909_1 by a first interval in the second horizontal direction (Y-direction), and third active patterns 909_3 spaced apart from the second active patterns 909_2 by a second interval greater than the first interval in the second horizontal direction (Y-direction).

The back gate electrode 26 described above may be replaced with a back gate electrode 926 extending in the first horizontal direction (X-direction), and the back gate dielectric layer 22 described above may be replaced with a back gate dielectric layer 922 disposed between the back gate electrode 926 and the active patterns 909, and between the back gate electrode 926 and the insulating pillar 905.

The word line 36 described above may be replaced with a word line 936 extending in the first horizontal direction (X-direction), and the cell gate dielectric layer 33 described above may be replaced with a cell gate dielectric layer 933 disposed between the word line 936 and the active patterns 909, and between the word line 936 and the insulating pillar 905.

The insulating pattern 48 described above may be replaced with an insulating pattern 948 extending in the first horizontal direction (X-direction).

The buffer insulating structure 18 (see FIG. 6B and FIG. 7A) described above may be replaced with insulating buffer structures 918 disposed between the first and second active patterns 909_1 and 909_2 and between the second and third active patterns 909_2 and 909_3. Each of the insulating buffer structures 918 may include a buffer pattern 916, a first buffer liner 914 covering a side surface and a lower surface of the buffer pattern 916, and a second buffer liner 912 covering an external surface and a lower surface of the first buffer liner 914. The insulating pillar 905 may extend upwardly between the insulating buffer structures 918, and may have an upper surface disposed on a higher level than those of upper surfaces of the back gate electrode 926 and the word line 936.

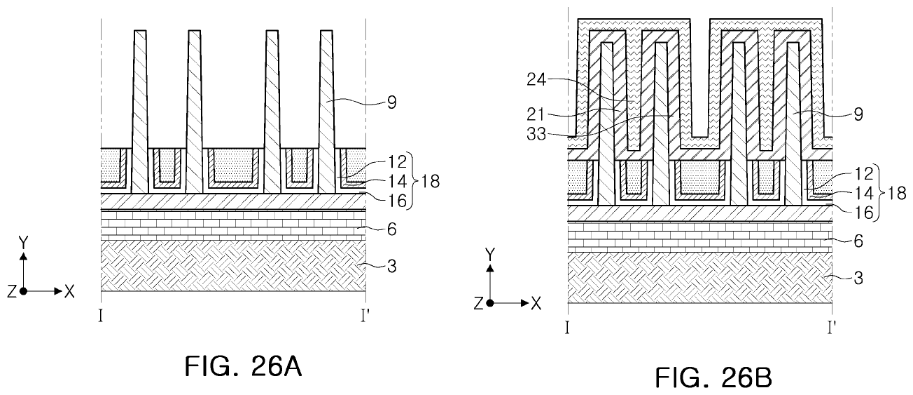

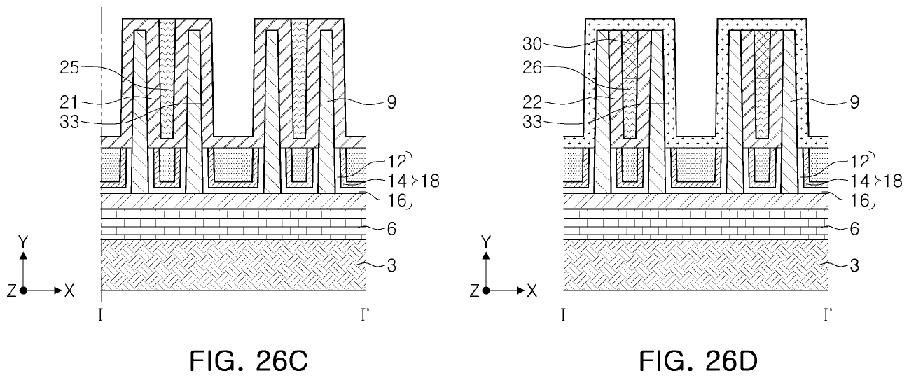

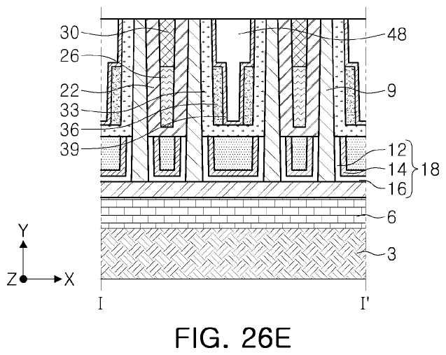

Next, an example of a method of forming a semiconductor device according to some example embodiments of the present disclosure will be described with reference to FIGS. 25 and 26A to 26E. FIG. 25 is a process flow diagram illustrating a method of forming a semiconductor device according to some example embodiments of the present disclosure, and FIGS. 26A to 26E are cross-sectional views illustrating a region taken along line I-I′ of FIG. 5A to describe an example of a method of forming a semiconductor device according to some example embodiments of the present disclosure.

Referring to FIGS. 25 and 26A, a base substrate 3 and an insulating layer 6 on the base substrate 3 may be formed. The base substrate 3 may be a semiconductor substrate. Active patterns 9 each having a bar shape may be formed (S10). The active patterns 9 may be formed on the insulating layer 6. Each of the active patterns 9 may have an inclined side surface so that a width of a lower surface thereof is larger than that of an upper surface thereof. Accordingly, the active patterns 9 may be formed without collapsing or deforming. The active patterns 9 may be formed of a semiconductor material.

An buffer insulating structure 18 surrounding side surfaces of lower regions of the active patterns 9 may be formed. The buffer insulating structure 18 may include a buffer pattern 16, a first buffer liner 14 covering a side surface and a lower surface of the buffer pattern 16, and a second buffer liner 12 covering an external surface and a lower surface of the first buffer liner 14.

Referring to FIG. 26B, a first gate dielectric layer 21 conformally covering an upper surface of the buffer insulating structure 18 and exposed surfaces of the active patterns 9 may be formed, and a conductive layer 24 may be formed on the first gate dielectric layer 21. The conductive layer 24 may fill a space between the active patterns 9 that are relatively close to each other.

Referring to FIG. 26C, the conductive layer 24 may be isotropically etched so that a conductive layer filling a space between the active patterns that are relatively close to each other, among the active patterns 9, may remain. The conductive layer remaining in this manner may be defined as a preliminary back gate electrode 25.

Referring to FIG. 25 and FIG. 26D, back gate electrodes 26 may be formed (S30). Forming the back gate electrodes 26 may include etching-back the preliminary back gate electrode 25. Back gate capping pattern 30 may be formed on the back gate electrodes 26. The first gate dielectric layer 21 may be isotropically etched so that the first gate dielectric layer 21 remains in contact with the back gate electrode 26 and the back gate capping pattern 30, thus forming the back gate dielectric layer 22.

Next, a second gate dielectric layer 33 may be formed (S40). The second gate dielectric layer 33 may be a cell gate dielectric layer. The second gate dielectric layer 33 may be conformally formed to cover side surfaces and upper surfaces of the active patterns 9 after the back gate dielectric layer 22 is formed.

Referring to FIGS. 25 and 26E, word lines 36 may be formed (S50). Forming the word lines 36 may include forming a conformal conductive layer on the cell gate dielectric layer 33 and anisotropically etching the conductive layer. Subsequently, an insulating liner 39 may be formed conformally, an insulating material may be formed on the insulating liner 39, and a planarization process may be performed until the upper surfaces of the active patterns 9 are exposed, thus forming an insulating pattern 48.

Referring to FIG. 25 and FIG. 7A described above, a semiconductor process may be performed to form the insulating structure 59 and the pad structures 66. Subsequently, an insulating etch stop layer 69 may be formed on the insulating structure 59 and the pad structures 66. A data storage structure 77 may be formed (S60). The data storage structure 77 may include first electrodes 71 penetrating through the insulating etch stop layer 69 and connected to the pad structures 66 and extending upwardly, a dielectric layer 73 disposed on the insulating etch stop layer 69 and the first electrodes 71, and a second electrode 75 on the dielectric layer 73.

Then, after removing the substrate 3 and the insulating layer 6, a semiconductor process of forming the bit lines 85 and the bit line shield structure 91 as per FIG. 7A may be performed.

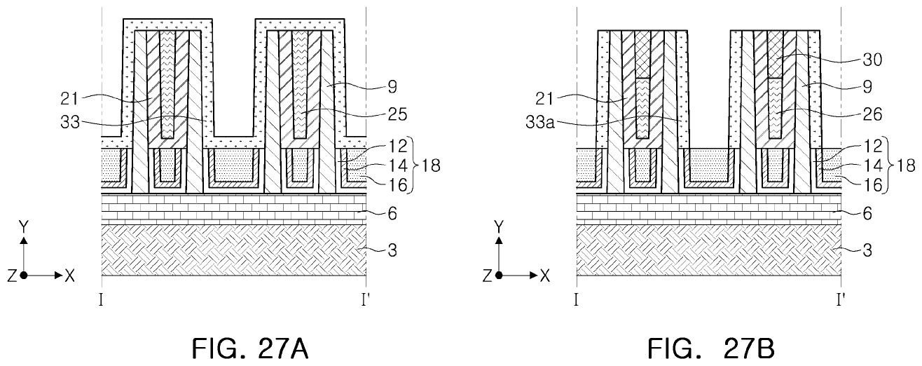

Next, an example of a method of forming a semiconductor device according to some example embodiments of the present disclosure will be described with reference to FIGS. 27A and 27B. FIGS. 27A and 27B are cross-sectional views illustrating a region taken along line I-I′ of FIG. 5A to illustrate an example of a method of forming a semiconductor device according to some example embodiments of the present disclosure.

Referring to FIG. 27A, a structure illustrated in FIG. 26c may be formed. Next, the first gate dielectric layer 21 (FIG. 26C) may be isotropically etched to reduce a thickness of the first gate dielectric layer 21 (see FIG. 26C). Next, a second gate dielectric layer 33 may be conformally formed. The second gate dielectric layer 33 may cover a portion of the side surfaces and the upper surfaces of each of the active patterns 9.

Referring to FIG. 27B, the second gate dielectric layer 33 (see FIG. 27A) may be anisotropically etched to form a cell gate dielectric layer 33a remaining on portions of the side surfaces of each of the active patterns 9. Next, the preliminary back gate electrode 25 may be etched-back to form a back gate electrode 26, and a back gate capping pattern 30 may be formed on the back gate electrode 26. Then, a semiconductor process of forming the word lines 36, the pad structures 66, the data storage structure 77, the bit lines 85, and the bit line shield structure 91 may be performed.

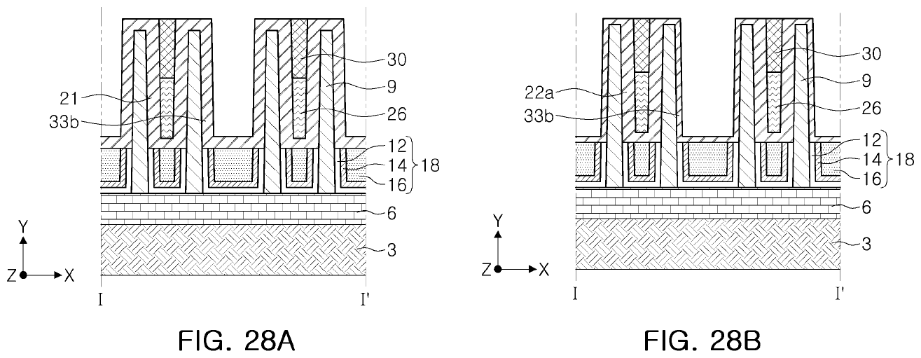

Next, an example of a method for forming a semiconductor device according to embodiments of the present disclosure will be described with reference to FIGS. 28a and 28b. FIGS. 28a and 28b are cross-sectional views illustrating a region taken along line I-I′ of FIG. 5A to illustrate an example of a method of forming a semiconductor device according to example embodiments of the present disclosure,

Referring to FIG. 28A, a structure may be formed up to the structure illustrated in FIG. 26C. Next, the preliminary back gate electrode 25 may be etched-back to form a back gate electrode 26, and a back gate capping pattern 30 may be formed on the back gate electrode 26.

Referring to FIG. 28B, an exposed region of the first gate dielectric layer 21 may be isotropically etched to reduce a thickness thereof. Accordingly, the first gate dielectric layer 21 may be formed of a back gate dielectric layer 22a remaining in contact with the back gate electrode 26 and the back gate capping pattern 30 and having a first thickness, and a cell gate dielectric layer 33b having a reduced thickness. Then, a semiconductor process of forming the word lines 36, the pad structures 66, the data storage structure 77, the bit lines 85, and the bit line shield structure 91 may be performed.

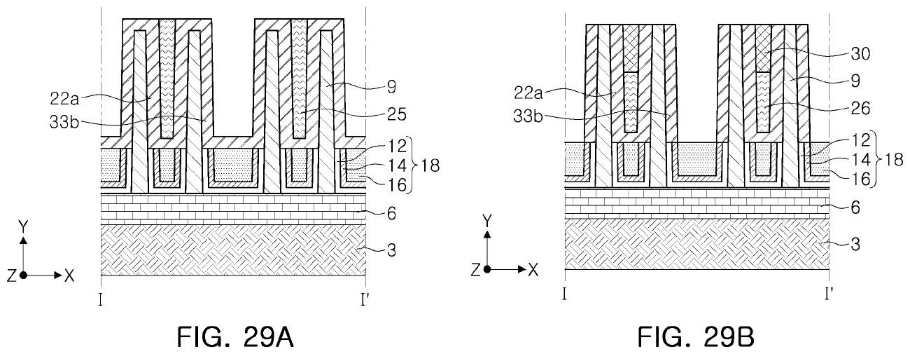

Next, an example of a method of forming a semiconductor device according to some example embodiments of the present disclosure will be described with reference to FIGS. 29A and 29B. FIGS. 28A and 28B are cross-sectional views illustrating a region taken along line I-I′ of FIG. 5A to illustrate an example of a method of forming a semiconductor device according to example embodiments of the present disclosure.

Referring to FIG. 29A, a structure may be formed up to the structure illustrated in FIG. 26C. Subsequently, an exposed region of the first gate dielectric layer 21 may be isotropically etched to reduce a thickness thereof. Accordingly, the first gate dielectric layer 21 may be formed of a back gate dielectric layer 22a remaining in contact with the preliminary back gate electrode 25 and having a first thickness, and a cell gate dielectric layer 33b having a reduced thickness.

Referring to FIG. 29B, the preliminary back gate electrode 25 may be etched-back to form a back gate electrode 26, and a back gate capping pattern 30 may be formed on the back gate electrode 26. Subsequently, the cell gate dielectric layer 33b may be anisotropically etched. Then, a semiconductor process of forming the word lines 36, the pad structures 66, the data storage structure 77, the bit lines 85 and the bit line shield structure 91 may be performed.

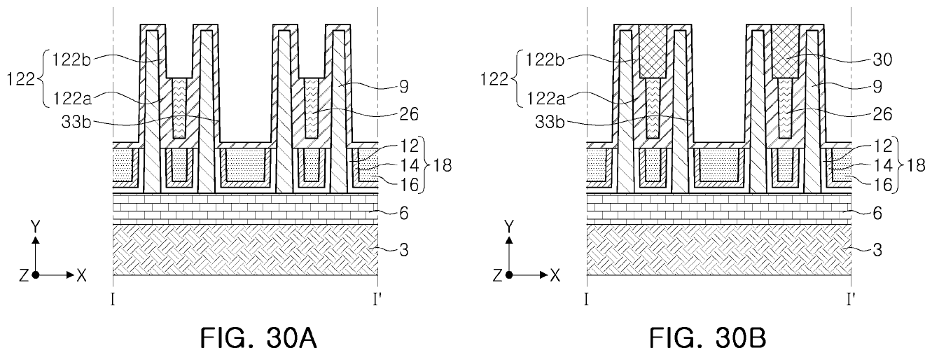

Next, an example of a method of forming a semiconductor device according to example embodiments of the present disclosure will be described with reference to FIGS. 30A and 30B. FIGS. 30A and 30B are cross-sectional views illustrating a region taken along line I-I′ of FIG. 5A to illustrate an example of a method of forming a semiconductor device according to some example embodiments of the present disclosure.

Referring to FIG. 30A, a structured may be formed up to the structure illustrated in FIG. 26C. Next, the preliminary back gate electrode 25 may be etched-back to form a back gate electrode 26. Next, the exposed region of the first gate dielectric layer 21 may be isotropically etched to reduce a thickness thereof. Accordingly, the first gate dielectric layer 21 may be formed of a first gate dielectric layer 122 including a first gate portion 122a contacting the back gate electrode 26 and having a first thickness and a second gate portion 122b having a second thickness lower than the first thickness in the remaining region.

Referring to FIG. 30B, a back gate capping pattern 30 may be formed on the back gate electrode 26. Then, a semiconductor process of forming the word lines 36, the pad structures 66, the data storage structure 77, the bit lines 85 and the bit line shield structure 91 may be performed.

According to some example embodiments, a cell transistor including a channel region extending in a vertical direction and a word line facing a first side surface of the channel region may be provided. Accordingly, the integration of a semiconductor device may be improved.

According to some example embodiments, a back gate facing a second side surface of the channel region may be provided. The back gate may improve the performance of the semiconductor device.

According to some example embodiments, a method forms a back gate and a word line sequentially after forming active patterns preferentially so that a width of each lower surface is larger than that of each upper surface. A semiconductor device formed by such a method may have improved performance and/or improved productivity.

Advantages and effects of the present application are not limited to the foregoing content and may be more easily understood in the process of describing a specific example embodiment of the present disclosure.

Although some example embodiments of the present disclosure have been described with reference to the accompanying drawings, it will be understood by those skilled in the art that the present disclosure may be implemented in other specific forms without changing its technical concepts or essential features. Therefore, it should be understood that the example embodiments described above are not limited in all respects.

What is claimed is:

1. A semiconductor device, comprising:
a first active pattern and a second active pattern arranged sequentially in a first horizontal direction; and
a back gate electrode and a first word line spaced apart from each other in a second horizontal direction, the second horizontal direction being perpendicular to the first horizontal direction,
wherein each of the first and second active patterns includes:
a first source/drain region;
a second source/drain region at a level higher than a level of the first source/drain region; and
a channel region between the first source/drain region and the second source/drain region,
wherein the channel regions of the first and second active patterns are between the back gate electrode and the first word line, and
wherein in a plan view, the back gate electrode includes:
a line portion having first regions respectively facing the first and second active patterns and a second region between the first regions;
a first protrusion protruding from the second region of the line portion in a direction toward the first word line; and
a second protrusion protruding from the second region of the line portion in a direction away from the first word line.

2. The semiconductor device of claim 1, wherein, in a plan view, the first word line includes a bent portion, the bent portion bent in a direction toward the first protrusion of the back gate electrode.

3. The semiconductor device of claim 2, wherein the bent portion of the first word line extends between the first active pattern and the second active pattern.

4. The semiconductor device of claim 1, further comprising:
a first gate dielectric layer between the back gate electrode and the first and second active patterns; and
a second gate dielectric layer between the first word line and the first and second active patterns,
wherein a thickness of the first gate dielectric layer is greater than a thickness of the second gate dielectric layer.

5. The semiconductor device of claim 1, further comprising:
a gate dielectric layer,
wherein the gate dielectric layer includes:
a first portion between the back gate electrode and the first and second active patterns;
a second portion between the first active pattern and the second active pattern; and
a third portion between the first word line and the first and second active patterns,
wherein the first portion, the second portion and the third portion are integrally formed, and
wherein a thickness of the first portion is greater than a thickness of the third portion.

6. The semiconductor device of claim 1, wherein each of the first and second active patterns includes:
a first side surface and a second side surface opposing each other in the second horizontal direction; and
a third side surface and a fourth side surface opposing each other in the first horizontal direction,
wherein the third side surface and the fourth side surface each has a convex shape in an outward direction, and
wherein the outward direction is in a direction away from a center between the third side surface and the fourth side surface.

7. The semiconductor device of claim 1, wherein each of the first and second active patterns includes:
a first side surface and a second side surface opposing each other in the second horizontal direction; and
a third side surface and a fourth side surface opposing each other in the first horizontal direction, and
wherein the third side surface and the fourth side surface each has a concave shape.

8. The semiconductor device of claim 1, wherein the first word line includes a first conductive layer and a second conductive layer, the first conductive layer being a different material from a material of the first conductive layer.

9. The semiconductor device of claim 1, wherein an upper surface of the back gate electrode is at a level different from a level of an upper surface of the first word line.

10. The semiconductor device of claim 1, further comprising:
a second word line facing the first word line and spaced apart from the first word line; and
an air gap between the first word line and the second word line.

11. The semiconductor device of claim 1, further comprising:
a second word line facing the first word line and spaced apart from the first word line; and
a conductive shield line between the first word line and the second word line.

12. The semiconductor device of claim 1, further comprising:
pad patterns electrically connected to the second source/drain regions of the first and second active patterns;
data storage structures on the pad patterns; and
bit line structures electrically connected to the first source/drain regions of the first and second active patterns.

13. A semiconductor device, comprising:
a first active pattern and a second active pattern, spaced apart from each other in a first horizontal direction;
a back gate electrode and a first word line spaced apart from each other in a second horizontal direction, the second horizontal direction being perpendicular to the first horizontal direction;
a gate dielectric structure disposed between the first and second active patterns and the back gate electrode and between the first and second active patterns and the first word line, the gate dielectric structure extending below a lower surface of the back gate electrode and a lower surface of the first word line; and
a buffer insulating structure below the gate dielectric structure,
wherein the buffer insulating structure surrounds a side surface of a lower region of each of the first and second active patterns,
wherein each of the first and second active patterns includes a channel region between the back gate electrode and the first word line, and
wherein each of the first and second active patterns includes an inclined side surface so that a width of an upper surface thereof is smaller than a width of a lower surface thereof.

14. The semiconductor device of claim 13, wherein the buffer insulating structure includes a buffer pattern and a first buffer liner covering a side surface and a lower surface of the buffer pattern, and
wherein, in a plan view, the first buffer liner surrounds the side surface of the lower region of the first active pattern and the side surface of the lower region of the second active pattern.

15. The semiconductor device of claim 14, wherein the buffer insulating structure further includes a second buffer liner between the first buffer liner and the side surface of the lower region of each of the first and second active patterns, and
wherein a material of the first buffer liner is a different material from a material of the second buffer liner and different from a material of the buffer pattern.

16. The semiconductor device of claim 13, further comprising:
pad patterns electrically connected to second source/drain regions of the first and second active patterns;
data storage structures on the pad patterns; and
bit line structures electrically connected to first source/drain regions of the first and second active patterns,
wherein for each respective one of the first and second source/drain regions,
the second source/drain region is at a level higher than a level of the first source/drain region, and
the channel region is between the first source/drain region and the second source/drain region.

17. A semiconductor device, comprising:
a first structure including a memory region; and
a second structure bonded to the first structure and including a peripheral circuit region,
wherein the memory region includes:
a first active pattern and a second active pattern arranged sequentially in a first horizontal direction;
a back gate electrode and a word line spaced apart from each other in a second horizontal direction, the second horizontal direction being perpendicular to the first horizontal direction; and
a gate dielectric structure between the first and second active patterns and the back gate electrode, and between the first and second active patterns and the word line,
wherein each of the first and second active patterns includes:
a first source/drain region;
a second source/drain region at a level higher than a level of the first source/drain region; and
a channel region between the first source/drain region and second source/drain region,
wherein the channel region is between the back gate electrode and the word line, and
wherein the gate dielectric structure includes a first gate dielectric portion disposed between the first and second active patterns and the back gate electrode, and extending between the first and second active patterns.

18. The semiconductor device of claim 17, wherein the gate dielectric structure extends from the first gate dielectric portion to a space between each of the first and second active patterns and the word line.

19. The semiconductor device of claim 17, wherein the gate dielectric structure further includes a second gate dielectric portion between the first and second active patterns and the word line, and extending between the first and second active patterns,
wherein at least a portion of a boundary between the first gate dielectric portion and the second gate dielectric portion is between the first and second active patterns.

20. The semiconductor device of claim 17, wherein the back gate electrode includes:
a line portion having first regions facing the first and second active patterns and a second region between the first regions;
a first protrusion protruding from the second region of the line portion in a direction toward the word line; and
a second protrusion protruding from the second region of the line portion in a direction away from the word line, and
wherein the word line includes a bent portion, the bent portion bent in a direction toward the first protrusion of the back gate electrode.
